(19) United States
(12) Patent Application Publication
(10) Pub. No.: US 2016/0341579 A1
(43) Pub. Date: Nov. 24, 2016

(54) GYROSCOPE AND IMAGE SENSOR SYNCHRONIZATION

(71) Applicant: InvenSense, Inc., San Jose, CA (US)

(72) Inventors: Taro KIMURA, San Francisco, CA (US); William Kerry KEAL, Santa Clara, CA (US); Geo GAO, Fremont, CA (US)

(73) Assignee: InvenSense, Inc., San Jose, CA (US)

(21) Appl. No.: 15/226,812

(22) Filed: Aug. 2, 2016

Related U.S. Application Data
(63) Continuation-in-part of application No. 14/510,224, filed on Oct. 9, 2014.
(60) Provisional application No. 62/202,121, filed on Aug. 6, 2015.

(51) Int. Cl. G01D 18/00; B81B 7/02

(52) U.S. Cl. CPC G01D 18/008; B81B 7/02; B81B 2201/0242; B81B 2201/0292

(57) ABSTRACT

In a method of gyroscope operation, at an input of a gyroscope, a synchronization signal provided by an image sensor is received. The synchronization signal is associated with the capture of a portion of an image frame by the image sensor. Responsive to receipt of the synchronization signal by the gyroscope, the gyroscope generates gyroscope data that is substantially synchronized in time with the synchronization signal. The gyroscope outputs the gyroscope data for use in stabilization of the portion of the image frame.

### CROSS-REFERENCE TO RELATED APPLICATIONS

This application is a continuation-in-part/divisional application of and claims priority to and benefit of co-pending U.S. patent application Ser. No. 14/510,224 filed on Oct. 9, 2014 entitled “System and Method for MEMS Sensor System Synchronization” by Andy Milota, James Lin, and William Kerry Keal, having Attorney Docket No. IVS-397, and assigned to the assignee of the present application, the disclosure of which is hereby incorporated herein by reference in its entirety.

This application claims priority to and benefit of co-pending U.S. Provisional Patent Application No. 62/202,121 filed on Aug. 6, 2015 entitled “Gyro Assisted Image Processing” by Carlo Murgia, James Lin, and William Kerry Keal, having Attorney Docket No. IVS-628, and assigned to the assignee of the present application, the disclosure of which is hereby incorporated herein by reference in its entirety.

### BACKGROUND

Advances in technology have enabled the introduction of electronic devices that feature an ever increasing set of capabilities. Smartphones, for example, now offer sophisticated computing and sensing resources together with expanded communication capability, digital imaging capability, and user experience capability. Likewise, tablets, wearables, media players, Internet connected devices (which may or may not be mobile), and other similar electronic devices have shared in this progress and often offer some or all of these capabilities. Many of the capabilities of electronic devices, and in particular mobile electronic devices, are enabled by sensors (e.g., accelerometers, gyroscopes, pressure sensors, thermometers, acoustic sensors, etc.) that are included in the electronic device. That is, one or more aspects of the capabilities offered by electronic devices will rely upon information provided by one or more of the sensors of the electronic device in order to provide or enhance the capability. In general, sensors detect or measure physical or environmental properties of the device or its surroundings, such as one or more of the orientation, velocity, and acceleration of the device, and/or one or more of the temperature, acoustic environment, atmospheric pressure, etc. of the device and/or its surroundings, among others.

### BRIEF DESCRIPTION OF DRAWINGS

The accompanying drawings, which are incorporated in and form a part of the Description of Embodiments, illustrate various embodiments of the subject matter and, together with the Description of Embodiments, serve to explain principles of the subject matter discussed below. Unless specifically noted, the drawings referred to in this Brief Description of Drawings should be understood as not being drawn to scale. Herein, like items are labeled with like item numbers.

FIG. 1 shows a block diagram of an example electronic device comprising sensor synchronization capability, in accordance with various aspects of the present disclosure.

FIG. 2 shows an example sensor system, in accordance with various aspects of the present disclosure.

FIG. 3 shows a timing diagram of an example synchronization scenario, in accordance with various aspects of the present disclosure.

FIG. 4 shows a timing diagram of an example synchronization scenario, in accordance with various aspects of the present disclosure.

FIG. 5 shows an example sensor system, in accordance with various aspects of the present disclosure.

FIG. 6 shows an example sensor system, in accordance with various aspects of the present disclosure.

FIG. 7 shows a high-level block diagram of a gyroscope in accordance with various aspects of the present disclosure.

FIG. 8A shows signal flow paths with respect to a block diagram of a portion of an example device, in accordance with various aspects of the present disclosure.

FIG. 8B shows signal flow paths with respect to a block diagram of a portion of an example device, in accordance with various aspects of the present disclosure.

FIG. 9A shows a timing diagram of various signals and data, in accordance with various aspects of the present disclosure.

FIG. 9B shows a timing diagram of various signals, counts, data, and messages, in accordance with various aspects of the present disclosure.

FIGS. 10A-10E illustrate flow diagrams of an example method of gyroscope operation, in accordance with various aspects of the present disclosure.

FIGS. 11A-11C illustrate flow diagrams of an example method of gyroscope operation, in accordance with various aspects of the present disclosure.

### DESCRIPTION OF EMBODIMENTS

Reference will now be made in detail to various embodiments of the subject matter, examples of which are illustrated in the accompanying drawings. While various embodiments are discussed herein, it will be understood that they are not intended to limit to these embodiments. On the contrary, the presented embodiments are intended to cover alternatives, modifications and equivalents, which may be included within the spirit and scope the various embodiments as defined by the appended claims. Furthermore, in this Description of Embodiments, numerous specific details are set forth in order to provide a thorough understanding of embodiments of the present subject matter. However, embodiments may be practiced without these specific details. In other instances, well known methods, procedures, components, and circuits have not been described in detail as not to unnecessarily obscure aspects of the described embodiments.

### Notation and Nomenclature

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be one or more self-consistent procedures or instructions leading to a desired result. The procedures are those requiring physical manipulations of physical quantities. Usually, although not necessarily, these quantities take the form of electrical or magnetic signals capable of being stored, transferred, combined, compared, and otherwise manipulated in an electronic device/component.

It should be borne in mind, however, that all of these and similar terms are to be associated with the appropriate physical quantities and are merely convenient labels applied to these quantities. Unless specifically stated otherwise as apparent from the following discussions, it is appreciated that throughout the description of embodiments, discussions utilizing terms such as “receiving,” “generating,” “outputting,” “supplementing,” “capturing,” “interpolating,” “extrapolating,” “including,” “utilizing,” and “transmitting,” or the like, refer to the actions and processes of an electronic device or component such as: a sensor processing unit, a sensor processor, a host processor, a processor, a sensor (e.g., a gyroscope), a memory, a mobile electronic device, or the like, or a combination thereof. The electronic device/component manipulates and transforms data represented as physical (electronic and/or magnetic) quantities within the registers and memories into other data similarly represented as physical quantities within memories or registers or other such information storage, transmission, processing, or display components.

Embodiments described herein may be discussed in the general context of processor-executable instructions residing on some form of non-transitory processor-readable medium, such as program modules or logic, executed by one or more computers, processors, or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example mobile electronic device(s) described herein may include components other than those shown, including well-known components.

The techniques described herein may be implemented in hardware, or a combination of hardware with firmware and/or software, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, perform one or more of the methods described herein. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor.

The various illustrative logical blocks, modules, circuits and instructions described in connection with the embodiments disclosed herein may be executed by one or more processors, such as one or more motion processing units (MPUs), sensor processing units (SPUs), audio processing units (APUs), host processor(s) or core(s) thereof, digital signal processors (DSPs), general purpose microprocessors, application specific integrated circuits (ASICs), application specific instruction set processors (ASIPs), field programmable gate arrays (FPGAs), or other equivalent integrated or discrete logic circuitry. The term “processor,” as used herein may refer to any of the foregoing structures or any other structure suitable for implementation of the techniques described herein. In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any conventional processor, controller, microcontroller, or state machine. A processor may also be implemented as a combination of computing devices, e.g., a combination of an SPU/MPU and a microprocessor, a plurality of microprocessors, one or more microprocessors in conjunction with an SPU core, MPU core, or any other such configuration.

In various example embodiments discussed herein, a chip is defined to include at least one substrate typically formed from a semiconductor material. A single chip may for example be formed from multiple substrates, where the substrates are mechanically bonded to preserve the functionality. Multiple chip (or multi-chip) includes at least 2 substrates, wherein the 2 substrates are electrically connected, but do not require mechanical bonding.

A package provides electrical connection between the bond pads on the chip (or for example a multi-chip module) to a metal lead that can be soldered to a printed circuit board (or PCB). A package typically comprises a substrate and a cover. An Integrated Circuit (IC) substrate may refer to a silicon substrate with electrical circuits, typically CMOS circuits. A MEMS substrate provides mechanical support for the MEMS structure(s). The MEMS structural layer is attached to the MEMS substrate. The MEMS substrate is also referred to as handle substrate or handle wafer. In some embodiments, the handle substrate serves as a cap to the MEMS structure.

In the described embodiments, an electronic device incorporating a sensor may, for example, employ a motion tracking module also referred to as Motion Processing Unit (MPU) that includes at least one sensor in addition to electronic circuits. The at least one sensor may comprise any of a variety of sensors, such as for example a gyroscope, a compass, a magnetometer, an accelerometer, a microphone, a pressure sensor, a proximity sensor, a moisture sensor, a temperature sensor, a biometric sensor, or an ambient light sensor, among others known in the art.

Some embodiments may, for example, comprise an accelerometer, gyroscope, and magnetometer or other compass technology, which each provide a measurement along three axes that are orthogonal relative to each other, and may be referred to as a 9-axis device. Other embodiments may, for example, comprise an accelerometer, gyroscope, compass, and pressure sensor, and may be referred to as a 10-axis device. Other embodiments may not include all the sensors or may provide measurements along one or more axes.

The sensors may, for example, be formed on a first substrate. Various embodiments may, for example, include solid-state sensors and/or any other type of sensors. The electronic circuits in the MPU may, for example, receive measurement outputs from the one or more sensors. In various embodiments, the electronic circuits process the sensor data. The electronic circuits may, for example, be implemented on a second silicon substrate. In some embodiments, the first substrate may be vertically stacked, attached and electrically connected to the second substrate in a single semiconductor chip, while in other embodiments, the first substrate may be disposed laterally and electrically connected to the second substrate in a single semiconductor package.

In an example embodiment, the first substrate is attached to the second substrate through wafer bonding, as described in commonly owned U.S. Pat. No. 7,104,129, to simultaneously provide electrical connections and hermetically seal the MEMS devices. This fabrication technique advantageously enables technology that allows for the design and manufacture of high performance, multi-axis, inertial sensors in a very small and economical package. Integration at the wafer-level minimizes parasitic capacitances, allowing for improved signal-to-noise relative to a discrete solution. Such integration at the wafer-level also enables the incorporation of a rich feature set which minimizes the need for external amplification.

In the described embodiments, raw data refers to measurement outputs from the sensors which are not yet processed. Motion data refers to processed raw data. Processing may, for example, comprise applying a sensor fusion algorithm or applying any other algorithm. In the case of a sensor fusion algorithm, data from one or more sensors may be combined and/or processed to provide an orientation of the device. In the described embodiments, an MPU may include processors, memory, control logic and sensors among structures.

### OVERVIEW OF DISCUSSION

Discussion herein is divided into three sections. Section 1 describes an example electronic device, components of may be utilized to employ circuits, techniques, methods and the like which are discussed in Section 2 and Section 3. Section 2 describes a system and method for MEMS sensor system synchronization. Section 3 describes gyroscope and image sensor synchronization.

Herein, in various device usage scenarios, for example for various applications, the timing at which sensor samples are acquired for one or more sensors may be important. For example, in a scenario in which image stabilization processing is performed, synchronizing the acquisition of gyroscope information with image information acquisition and/or knowing the timing differential may be beneficial. In general, sensor circuits and/or systems may comprise internal timers that are utilized for sensor sampling.

Accordingly, various aspects of this disclosure comprise a system, device, and/or method for synchronizing sensor data acquisition and/or output. For example, various aspects of this disclosure provide a system and method for a host (or other circuit) that sends a synchronization signal to a sensor circuit when the host (or other circuit) determines that such a synchronization signal is warranted. Also for example, various aspects of this disclosure provide a system and method by which a sensor circuit that already comprises an internal clock to govern sampling can receive and act on a synchronization signal. Other aspects of this disclosure describe some uses for synchronized data (and in some instances additional data) that is output from a sensor such as synchronizing gyroscope data with image data from an image sensor.

### Section 1: Example Electronic Device

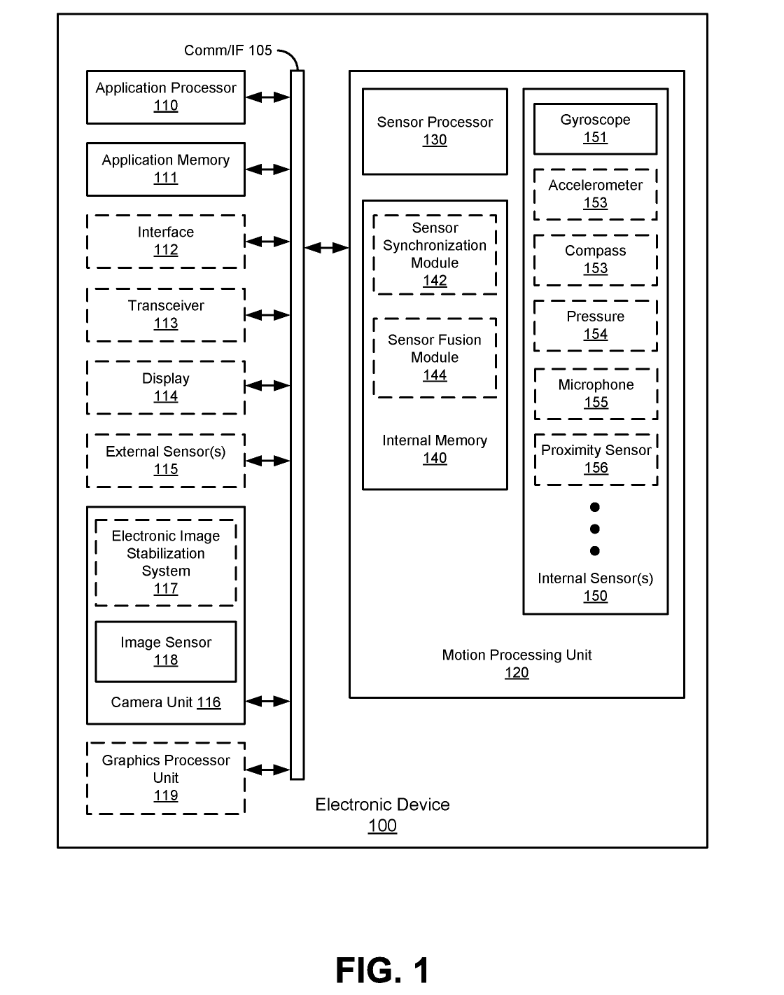

Turning first to FIG. 1, such figure shows a block diagram of an example electronic device comprising sensor synchronization capability, in accordance with various aspects of the present disclosure. As will be appreciated, the device 100 may be implemented as a mobile electronic device or apparatus, such as a handheld and/or wearable device (e.g., a watch, a headband, a pendant, an armband, a belt-mounted device, eyeglasses, a fitness device, a health monitoring device, etc.) that can be held in the hand of a user and/or worn on the person of the user and when moved in space by a user its motion and/or orientation in space are therefore sensed. For example, such a handheld device may be a mobile phone (e.g., a cellular phone, a phone running on a local network, or any other telephone handset), wired telephone (e.g., a phone attached by a wire and/or optical tether), personal digital assistant (PDA), pedometer, personal activity and/or health monitoring device, video game player, video game controller, navigation device, mobile internet device (MID), personal navigation device (PND), digital still camera, digital video camera, a tablet computer, a notebook computer, binoculars, telephoto lens, portable music, video, or media player, remote control, or other handheld device, a wristwatch, a mobile IOT device, or a combination of one or more of these devices.

In some embodiments, the device 100 may be a self-contained device that comprises its own display and/or other output devices in addition to input devices as described below. However, in other embodiments, the device 100 may function in conjunction with another portable device or a non-portable device such as a desktop computer, electronic tabletop device, server computer, etc., which can communicate with the device 100, e.g., via network connections. The device 100 may, for example, be capable of communicating via a wired connection using any type of wire-based communication protocol (e.g., serial transmissions, parallel transmissions, packet-based data communications), wireless connection (e.g., electromagnetic radiation, infrared radiation or other wireless technology), or a combination of one or more wired connections and one or more wireless connections.

As shown, the example device 100 comprises a communication interface 105, an application (or host) processor 110, application (or host) memory 111, a camera unit 116 with an image sensor 118, and a motion processing unit (MPU) 120 with at least one motion sensor such as a gyroscope 151. With respect to FIG. 1, components showed in broken line (i.e., dashed boxes) may not be included in some embodiments. Accordingly, in some embodiments, device 100 may include one or some combination of: interface 112, transceiver 113, display 114, external sensor(s) 115, an electronic image stabilization system 117 (disposed internal or external to camera unit 116), and a graphics processing unit. As depicted in FIG. 1, included components are communicatively coupled with one another, such as, via communication bus interface 105.

The application processor 110 (for example, a host processor) may, for example, be configured to perform the various computations and operations involved with the general function of the device 100 (e.g., running applications, performing operating system functions, performing power management functionality, controlling user interface functionality for the device 100, etc.). Application processor 110 can be one or more microprocessors, central processing units (CPUs), DSPs, general purpose microprocessors, ASICs, ASIPs, FPGAs or other processors which run software programs or applications, which may be stored in application memory 111, associated with the functions and capabilities of mobile electronic device 100. The application processor 110 may, for example, be coupled to MPU 120 through a communication interface 105, which may be any suitable bus or interface, such as a peripheral component interconnect express (PCIe) bus, a universal serial bus (USB), a universal asynchronous receiver/transmitter (UART) serial bus, a suitable advanced microcontroller bus architecture (AMBA) interface, an Inter-Integrated Circuit (I2C) bus, a serial digital input output (SDIO) bus, or other equivalent.

The application memory 111 (for example, a host memory) may comprise programs, drivers or other data that utilize information provided by the MPU 120. Details regarding example suitable configurations of the application (or host) processor 110 and MPU 120 may be found in co-pending, commonly owned U.S. patent application Ser. No. 12/106,921, filed Apr. 21, 2008. Application memory 111 an be any suitable type of memory, including but not limited to electronic memory (e.g., read only memory (ROM), random access memory, or other electronic memory), hard disk, optical disk, or some combination thereof. Multiple layers of software can be stored in application memory 111 for use with/operation upon application processor 110. In some embodiments, a portion of application memory 111 may be utilized as a buffer for data from one or more of the components of device 100.

Interface 112, when included, can be any of a variety of different devices providing input and/or output to a user, such as audio speakers, touch screen, real or virtual buttons, joystick, slider, knob, printer, scanner, computer network I/O device, other connected peripherals and the like.

Transceiver 113, when included, may be one or more of a wired or wireless transceiver which facilitates receipt of data at mobile electronic device 100 from an external transmission source and transmission of data from mobile electronic device 100 to an external recipient. By way of example, and not of limitation, in various embodiments, transceiver 113 comprises one or more of: a cellular transceiver, a wireless local area network transceiver (e.g., a transceiver compliant with one or more Institute of Electrical and Electronics Engineers (IEEE) 802.11 specifications for wireless local area network communication), a wireless personal area network transceiver (e.g., a transceiver compliant with one or more IEEE 802.15 specifications for wireless personal area network communication), and a wired a serial transceiver (e.g., a universal serial bus for wired communication).

Display 114, when included, may be a liquid crystal device, (organic) light emitting diode device, or other display device suitable for creating and visibly depicting graphic images and/or alphanumeric characters recognizable to a user. Display 114 may be configured to output images viewable by the user and may additionally or alternatively function as a viewfinder for camera unit 116.

External sensor(s) 115, when included, may comprise, without limitation, one or more or some combination of: a temperature sensor, an atmospheric pressure sensor, an infrared sensor, an ultrasonic sensor, a radio frequency sensor, a navigation satellite system sensor (such as a global positioning system receiver), an acoustic sensor (e.g., a microphone), an image sensor, an inertial or motion sensor (e.g., a gyroscope, accelerometer, or magnetometer) for measuring the orientation or motion of the sensor in space, a proximity sensor, an ambient light sensor, a biometric sensor, and a moisture sensors, or other type of sensor for measuring other physical or environmental quantities. External sensor 115 is depicted as being coupled with communication interface 105 for communication with application processor 110, application memory 111, and/or other components, this coupling may be by any suitable wired or wireless means. It should be appreciated that, as used herein, the term “external sensor” generally refers to a sensor that is carried on-board device 100, but that is not integrated into (i.e., internal to) the MPU 120.

Camera unit 116, when included, typically includes an optical element, such as a lens which projects an image onto an image sensor 118 of camera unit 116. Camera unit 116 may include an Electronic Image Stabilization (EIS) system 117. The processing for the EIS may also be performed by another processor, such as e.g. Application processor 110. In EIS system 117, the image stabilization is performed using image processing. For example, in video streams the motion of the device will result in each frames being displaced slightly with respect to each other, leading to shaky video results. The EIS system 117 analyzes these displacements (as measured by motion sensors such as gyroscope 151 and/or accelerometer 153) using image processing techniques, and corrects for this motion by moving the individual image frames so that they align. The displacement vectors between the images may also be determined (partially) using motion sensors. For example, gyroscope data, in the form of angular velocities measured by the gyroscope 151, from gyroscope 151 are used to help determine the displacement vector from one frame to the next frame. EIS systems that use gyroscope data may be referred to as gyroscope-assisted EIS systems. The required image processing may be performed by one or more of: a processor incorporated in camera unit 116, sensor processor 130, host processor 110, graphics processor unit 119, and/or any other dedicated image or graphical processor.

In some embodiments camera unit 116 may include an Optical Image Stabilization (OIS) system (not depicted). In optical image stabilization, the optical element may be moved with respect to the image sensor 118 in order to compensate for motion of the mobile electronic device. OIS systems typically include/utilize processing to determine compensatory motion of the optical element of camera unit 116 in response to sensed motion of the mobile electronic device 100 or portion thereof, such as the camera unit 116 itself. Actuators within camera unit 116 operate to provide the compensatory motion in the image sensor 118, lens, or both, and position sensors may be used to determine whether the actuators have produced the desired movement. In one aspect, an actuator may be implemented using voice coil motors (VCM) and a position sensor may be implemented with Hall sensors, although other suitable alternatives may be employed. Camera unit 116 may have its own dedicated motion sensors to determine the motion, may receive motion data from a motion sensor external to camera unit 116 (e.g., in motion processing unit 120), or both. The OIS controller may be incorporated in camera unit 116, or may be external to camera unit 116. For example, sensor processor 130 may analyze the motion detected by gyroscope 151 and send control signals to the electronic image stabilization system 117, the OIS, or both.

Mobile electronic device 100 and more particularly camera unit 116 may have both an OIS system and an EIS system 117, which each may work separately under different conditions or demands, or both systems may work in combination. For example, the OIS may perform a first stabilization, and the EIS system 117 may perform a subsequent second stabilization, in order to correct for motion that the OIS system was not able to compensate. The EIS system 117 may be a conventional system purely based on image processing, or a gyroscope-assisted EIS system. In the case of a gyroscope-assisted EIS system, the EIS and OIS systems may use dedicated gyroscope sensors, or may use the same gyroscope sensor (e.g., gyroscope 151).

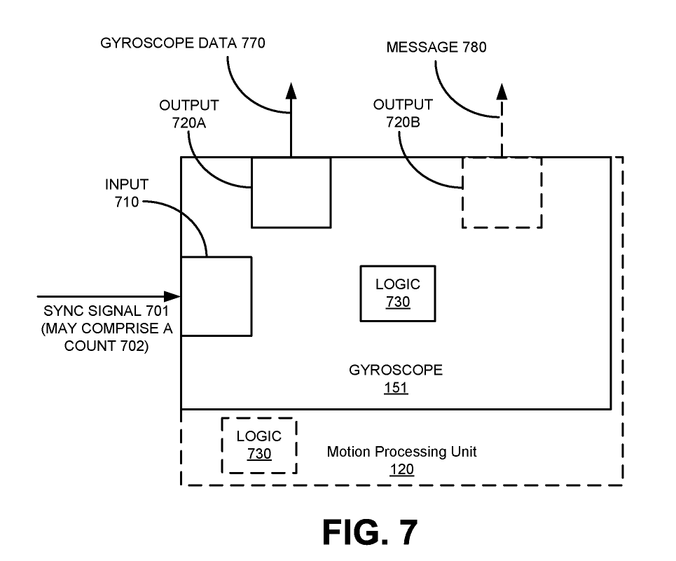

Image sensor 118 is a sensor that electrically detects and conveys the information that constitutes an image. The detection is performed by converting light waves that reach the image sensor into electrical signals representative of the image information that the light waves contain. Any suitable sensor may be utilized as image sensor 118, including, but not limited to a charge coupled device or a metal oxide semi-conductor device. In some embodiments, image sensor 118 (or a processor, logic, I/O, or the like coupled therewith) outputs a synchronization signal (illustrated as 701 in FIGS. 7, 8A, 8B, 9A, and 9B). The image sensor 118 (or some other portion of camera unit 116) may produce a synchronization (“sync”) signal, for example: a frame-sync signal synchronized and output in concert with capture of a full image frame by image sensor 118; a line-sync signal synchronized and output in concert with capture of a full line of an image frame, a sub-line sync signal synchronized and output in concert with the capture of some portion of image pixel that are less than a full line, and a sub-frame sync signal synchronized and output in concert with capture of a sub-portion of an entire frame that is less than the a full frame and more than a single line (e.g., one quarter of a frame, one third of a frame, etc.). Such sync signals may be communicated over communication bus/interface 105 to motion processing unit 120 (and to one or more components thereof, such as gyroscope 151). Alternatively, dedicated hardware connections, such as e.g., interrupt lines, may be used for communicating sync signals to their desired location(s). In various embodiments, the synchronization signal 701 may comprise one or some combination of a (digital or analog) pulse and a data string. In some embodiments, the data string may comprise one or more of a command and a count 702 that is internally generated and incremented by image sensor 118. For example, the count 702 may be incremented each time that a synchronization signal is output and may be associated with the image frame or portion thereof that the sync signal is synchronized with. Camera unit 116 may comprise an image processor (not depicted) which may be used for control of the image sensor and any type of local image processing. The image processor may also control communication such as sending and receiving information, e.g. the sync signals, messages, and counters.

Graphics processing unit (GPU) 119 is a processor optimized for processing images and graphics and typically includes hundreds of processing cores that are configured for handling, typically, thousands of similar threads simultaneously via parallel processing. In contrast, application processor 110 is typically a general purpose processor which includes only one or at the most several processing cores.

In this example embodiment, the MPU 120 is shown to comprise a sensor processor 130, internal memory 140 and one or more internal sensors 150.

Sensor processor 130 can be one or more microprocessors, CPUs, DSPs, general purpose microprocessors, ASICs, ASIPs, FPGAs or other processors which run software programs, which may be stored in memory internal memory 140 (or elsewhere), associated with the functions of motion processing unit 120.

Internal memory 140 may store algorithms, routines or other instructions for instructing sensor processor 130 on the processing of data output by one or more of the internal sensors 150, including the sensor synchronization module 142 (when included) and sensor fusion module 144 (when included), as described in more detail herein. In some embodiments, a portion of internal memory 140 may be utilized as a buffer for data output by one or more sensors 150 (e.g., as a buffer for gyroscope data and/or messages output by gyroscope 151).

As used herein, the term “internal sensor” generally refers to a sensor implemented, for example using MEMS techniques, for integration with the MPU 120 into a single chip. Internal sensor(s) 150 may, for example and without limitation, comprise one or more or some combination of: a gyroscope 151, an accelerometer 152, a compass 153 (for example a magnetometer), a pressure sensor 154, a microphone 155, a proximity sensor 156, etc. Though not shown, the internal sensors 150 may comprise any of a variety of sensors, for example, a temperature sensor, light sensor, moisture sensor, biometric sensor, image sensor, etc. The internal sensors 150 may, for example, be implemented as MEMS-based motion sensors, including inertial sensors such as a gyroscope or accelerometer, or an electromagnetic sensor such as a Hall effect or Lorentz field magnetometer. In some embodiments, at least a portion of the internal sensors 150 may also, for example, be based on sensor technology other than MEMS technology (e.g., CMOS technology, etc.). As desired, one or more of the internal sensors 150 may be configured to provide raw data output measured along three orthogonal axes or any equivalent structure.

Even though various embodiments may be described herein in the context of internal sensors implemented in the MPU 120, these techniques may be applied to a non-integrated sensor, such as an external sensor 115, and likewise the sensor synchronization module 142 (when included) and/or sensor fusion module 144 (when included) may be implemented using instructions stored in any available memory resource, such as for example the application memory 111, and may be executed using any available processor, such as the application (or host) processor 110. Still further, the functionality performed by the sensor synchronization module 142 may be implemented using hardware, or a combination of hardware with firmware and/or software

As will be appreciated, the application (or host) processor 110 and/or sensor processor 130 may be one or more microprocessors, central processing units (CPUs), microcontrollers or other processors which run software programs for the device 100 and/or for other applications related to the functionality of the device 100. For example, different software application programs such as menu navigation software, games, camera function control, navigation software, and phone or a wide variety of other software and functional interfaces can be provided. In some embodiments, multiple different applications can be provided on a single device 100, and in some of those embodiments, multiple applications can run simultaneously on the device 100. Multiple layers of software can, for example, be provided on a computer readable medium such as electronic memory or other storage medium such as hard disk, optical disk, flash drive, etc., for use with application processor 110 and sensor processor 130. For example, an operating system layer can be provided for the device 100 to control and manage system resources in real time, enable functions of application software and other layers, and interface application programs with other software and functions of the device 100. In various example embodiments, one or more motion algorithm layers may provide motion algorithms for lower-level processing of raw sensor data provided from internal or external sensors. Further, a sensor device driver layer may provide a software interface to the hardware sensors of the device 100. Some or all of these layers can be provided in the application memory 111 for access by the application processor 110, in internal memory 140 for access by the sensor processor 130, or in any other suitable architecture (e.g., including distributed architectures).

In some example embodiments, it will be recognized that the example architecture depicted in FIG. 1 may provide for sensor synchronization to be performed using the MPU 120 and might not require involvement of the application processor 110 and/or application memory 111. Such example embodiments may, for example, be implemented with one or more internal sensor sensors 150 on a single substrate. Moreover, as will be described below, the sensor synchronization techniques may be implemented using computationally efficient algorithms to reduce processing overhead and power consumption.

As discussed herein, various aspects of this disclosure may, for example, comprise processing various sensor signals indicative of device orientation and/or location. Non-limiting examples of such signals are signals that indicate accelerometer, gyroscope, and/or compass orientation in a world coordinate system.

In an example implementation, an accelerometer, gyroscope, and/or compass circuitry may output a vector indicative of device orientation. Such a vector may, for example, initially be expressed in a body (or device) coordinate system. Such a vector may be processed by a transformation function, for example based on sensor fusion calculations, that transforms the orientation vector to a world coordinate system. Such transformation may, for example, be performed sensor-by-sensor and/or based on an aggregate vector based on signals from a plurality of sensors.

As mentioned herein, the sensor synchronization module 142 or any portion thereof may be implemented by a processor (e.g., the sensor processor 130) operating in accordance with software instructions (e.g., sensor synchronization module software) stored in the internal memory 140, or by a pure hardware solution (e.g., on-board the MPU 120). Also for example, the sensor synchronization module 142 or any portion thereof may be implemented by the application processor 110 (or other processor) operating in accordance with software instructions stored in the application memory 111, or by a pure hardware solution (e.g., on-board the device 100 external to the MPU 120).

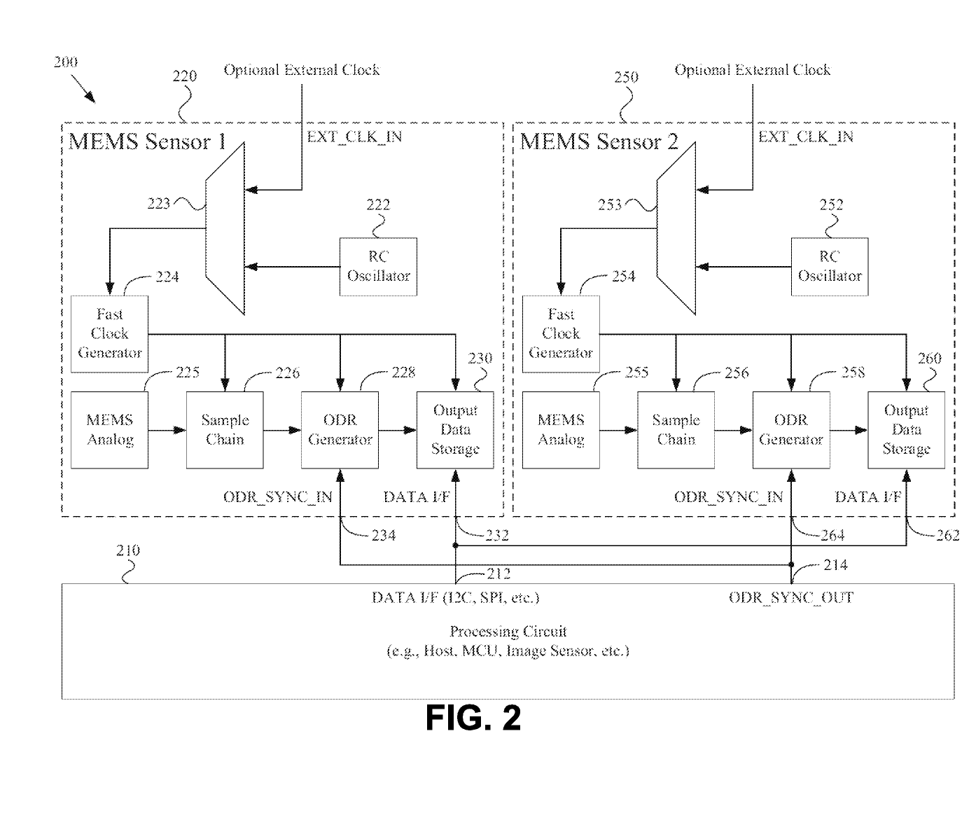

The discussion of FIGS. 2-6 will provide further example details of at least the operation of the sensor synchronization module 142. It should be understood that any or all of the functional modules discussed herein may be implemented in a pure hardware implementation and/or by one or more processors operating in accordance with software instructions. It should also be understood that any or all software instructions may be stored in a non-transitory computer-readable medium.

### Section 2: System and Method for MEMS Sensor System Synchronization

Turning next to FIG. 2, such figure shows an example sensor system, in accordance with various aspects of the present disclosure. The example sensor system 200 may, for example, be used to synchronize sensors of a handheld device (e.g., a mobile telephone, PDA, camera, portable media player, gaming device, etc.). Note, however, that the sensor system 200 is not limited to handheld devices, for example being readily applicable to wearable devices (e.g., a watch, a headband, an armband, a belt-mounted device, eyeglasses, a fitness device, a health monitoring device, etc.) and other devices. The example sensor system 200 may, for example, share any or all characteristics with the example device 100 illustrated in FIG. 1 and discussed herein. For example, the sensor system 200 or any portion thereof may be implemented with the sensor processor 130 of FIG. 1 operating in accordance with software instructions in the sensor synchronization module 142 stored in the internal memory 140. Also for example, the sensor system 200 or any portion thereof may be implemented with the application (or host) processor 110 operating in accordance with software instructions stored in the application memory 111.

The sensor system 200 may, for example, comprise a processing circuit 210 that utilizes one or more sensor circuits for acquiring various sensed information and/or information derived therefrom. The processing circuit 210 may comprise characteristics of any of a variety of circuit types. For example, the processing circuit 210 may comprise one or more of a host circuit (e.g., an application processor, modem application processor, etc.), a microcontroller unit (e.g., a sensor hub, etc.), a sensor processor, an image sensor or image processor, etc. The processing circuit 210 may, for example, share any or all characteristics with the application processor 110 and/or sensor processor 130 of the example system 100 illustrated in FIG. 1 and discussed herein. The processing circuit 210 is depicted as a single block, but this does not mean it has to be a dedicated block. Rather, it may be seen as a virtual processing circuit made up of one or more component of electronic device 100. For example, any of the synchronization signals may come from sensor processor 130 or from (an image processor in) camera unit 116 and will be considered as part of processing circuit 210.

The sensor system 200 may, for example, comprise one or more sensor circuits utilized by the processing circuit 210. Two example sensor circuits 220 and 250 are shown in the example system 200, but the scope of this disclosure is not limited to any particular number of sensor circuits. The sensor circuits 220 and 250 may, for example, comprise one or more MEMS sensors and/or non-MEMS sensors. The sensor circuits 220 and 250 may, for example, share any or all characteristics with the internal sensors 150 and/or external sensors 115 of the system 100 illustrated in FIG. 1 and discussed herein.

One or more of the sensor circuits 220 and 250 may, for example, comprise an integrated circuit in a single electronic package. One or more of the sensor circuits 220 and 250 may, for example, comprise a chip set. Also for example, one or more of the sensor circuits 220 and 250 may comprise a portion of a larger integrated device, for example a system on a chip, a multi-die single-package system, etc.

One or more of the sensor circuits 220 and 250 may, for example, comprise a MEMS gyroscope circuit. Also for example, one or more of the sensor circuits 220 and 250 may comprise an integrated MEMS gyro and accelerometer circuit (e.g., on a same die and/or in a same package). Additionally, for example, one or more of the sensor circuits 220 and 250 may comprise an integrated MEMS gyro, accelerometer, and compass circuit (e.g., on a same die and/or in a same package). Further for example, one or more of the sensor circuits 220 and 250 may comprise an integrated MEMS gyro, accelerometer, compass, and pressure sensor circuit (e.g., on a same die and/or in a same package). Still further for example, one or more of the sensor circuits 220 and 250 may comprise an integrated MEMS gyro, accelerometer, compass, pressure sensor, and microphone circuit (e.g., on a same die and/or in a same package, in different packages, etc.). The one or more sensors 220 and 250 may also comprise biometric sensors, temperature sensors, moisture sensors, light sensors, proximity sensors, etc. (e.g., on a same die and/or in a same package, in different packages, etc.).

A first sensor circuit 220 may, for example, comprise an RC oscillator module 222 that is utilized to generally control the timing of sensing, sensor data processing, and/or data I/O activities of the first sensor circuit 220. The RC oscillator module 222 may, for example, be a relatively low-quality, cheap, and low-power device. For example, the RC oscillator module 222 may be characterized by 10K or more ppm stability. Also for example, the RC oscillator module 222 may be characterized by 5K or more ppm stability, 20K or more ppm stability, 100K or more ppm stability, etc.

The output signal of the RC oscillator module 222 may, for example, be input to a fast clock generator module 224, for example directly or through a multiplexing circuit 223, which provides clock signals to various sensor processing modules of the first sensor circuit 220, for example based on the output of the RC oscillator module 222. For example, the fast clock generator module 224 may provide a clock signal to a sample chain module 226, an output data rate (ODR) generator module 228, an output data storage module 230, etc. The multiplexing circuit 223 may also receive an external clock signal at an external clock input 234. The multiplexing circuit 223 may, for example under the control or the processing circuit 210 and/or the first sensor circuit 220, select whether to provide an external clock signal received at the external clock input 234 or the clock (or timing) signal received from the RC oscillator module 222 to the fast clock generator module 224.

The first sensor circuit 220 may also, for example, comprise a MEMS analog module 225. The MEMS analog module 225 may, for example, comprise the analog portion of a MEMS sensor (e.g., any of the MEMS sensors discussed herein, or other MEMS sensors).

The first sensor circuit 220 may also comprise a sample chain module 226. The sample chain module 226 may, for example, sample one or more analog signals output from the MEMS analog module 225 and convert the samples to one or more respective digital values. In an example implementation, the sample chain module 226 may, for example, comprise a sigma-delta A/D converter that is oversampled and accumulated, for example to output a 16-bit digital value.

The first sensor circuit 220 may additionally, for example, comprise an output data rate (ODR) generator module 228 that, for example, stores digital sensor information from the sample chain module 226 in the output data storage module 230 at an output data rate (ODR).

The first sensor circuit 220 may further, for example, provide a data interface 232, for example at the output of the output data storage module 230 (e.g., a register or bank thereof, a general memory, etc.), via which the processing circuit 210 may communicate with the first sensor circuit 220. For example, the processing circuit 210 may be communicatively coupled to the first sensor circuit 220 via a data bus interface 212 (e.g., an I2C interface, an SPI interface, etc.).

Though the first sensor circuit 220 is illustrated with a single MEMS analog module 225, sample chain module 226, ODR generator module 228, and output data storage module 230, such a single set of modules is presented for illustrative clarity and not for limitation. For example, the first sensor circuit 220 may comprise a plurality of MEMS analog modules, each corresponding to a respective sample chain module, ODR generator module, and/or output data storage module.

Note that the first sensor circuit 220 may also comprise one or more processors that process the sensor information to output information of device location, orientation, etc. For example, the information output to the output data storage module 230 may comprise raw sensor data, motion data, filtered sensor data, sensor data transformed between various coordinate systems, position information, orientation information, timing information, etc.

The first sensor circuit 220 may, for example, comprise a sync signal input 234 that receives a sync signal, for example a pulse, from an external source and aligns the output data rate (ODR) of the first sensor circuit 220 to the received pulse. The pulse may, for example, comprise an ODR_SYNC_IN pulse. The sync signal input 234 may, for example, be coupled to the ODR generator module 228 within the first sensor circuit 220. The sync signal input 234 may, for example, receive a sync signal from the processing circuit 210 (e.g., from a sync signal output 214 of the processing circuit 210).

The second sensor circuit 250 may, for example, share any or all characteristics with the example first sensor circuit 220 discussed herein. For example, as with the first sensor circuit 220, the second sensor circuit 250 may comprise an RC oscillator module 252, multiplexer 253, fast clock generator module 254, MEMS analog module 255, sample chain module 256, ODR generator module 258, output data storage module 260, data interface 262, and sync signal input 264.

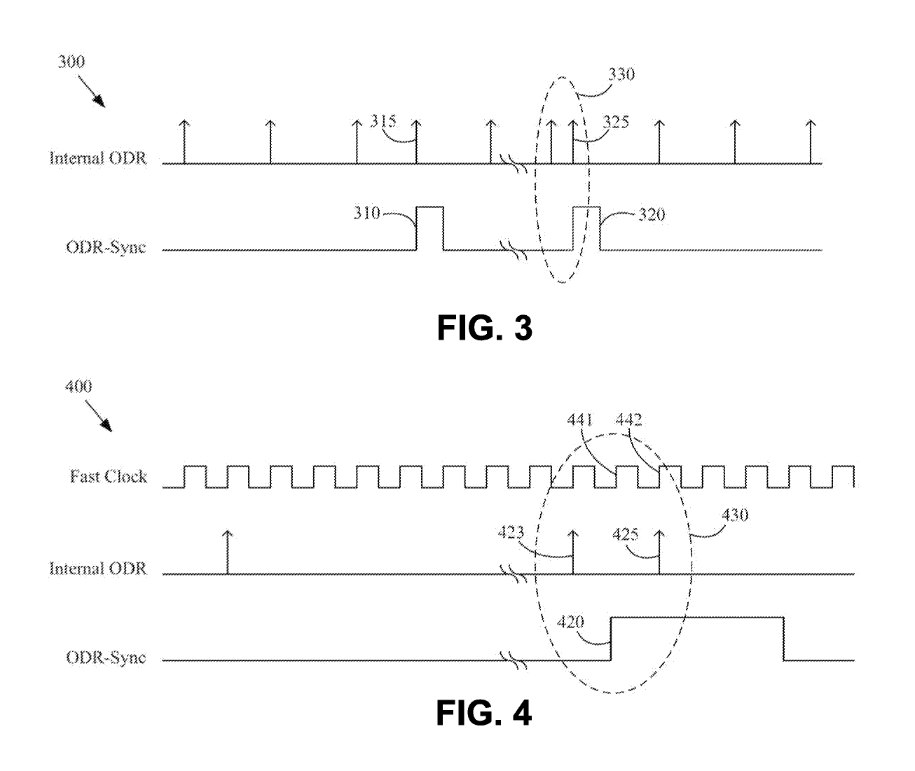

FIG. 3 shows a timing diagram 300 of an example synchronization scenario, in accordance with various aspects of the present disclosure. The top time line of the timing diagram 300, labeled “Internal ODR” illustrates the internal output data rate (ODR) of the sensor circuit (e.g., of first sensor circuit 220, second sensor circuit 250, any sensor circuit discussed herein, a general sensor circuit, etc.). The internal ODR may, for example, be generated by the ODR generator module 228. Though ideally, the ODR may occur at a constant period, in practice the ODR period may drift. For example, as explained herein, an oscillator module (e.g., the RC oscillator modules 222 and 252, or any oscillator module discussed herein) may be constructed with economic efficiency and/or power efficiency taking priority over performance. An example of such oscillator drift may, for example, be seen in the inconsistent time intervals between the internal ODR pulses as shown on the Internal ODR time line of FIG. 3.

The bottom time line of the timing diagram 300, labeled “ODR-Sync” illustrates a sync signal (e.g., the ODR-Sync signal output from the sync signal output 214 of the processing circuit 210, any synchronization signal discussed herein, a general synchronization signal, etc.). As shown in FIG. 3, when the first sync pulse 310 is communicated, for example from the processing circuit 210 to the sensor circuit 220, the internal ODR signal 315 is shifted to align with the first sync pulse 310. At some later time, when the second sync pulse 320 is communicated from the processing circuit 210 to the sensor circuit 220, the internal ODR signal 325 is shifted to align with the second sync pulse. For example, though the ODR generator module 228 would not ordinarily be ready yet to capture and store data from the sample chain module 226, the arrival of the second sync pulse 320 may force the ODR generator module 228 to act. This example synchronization occurrence is labeled 330 and will be referred to elsewhere herein.

As another example, the ODR generator module 228 may generally attempt to operate periodically with a target period of T. At a first time, the ODR generator module 228 acquires first sensor data from the sample chain 226 and stores the acquired first sensor data in the output data storage module 230. Under normal operation, the ODR generator module 228 would then wait until a second time that equals the first time plus the target period of T, and then acquire and store second sensor data. Since, however, the RC oscillator module 222 is imperfect, the operation of the ODR generator module 228 may have fallen behind. Continuing the example, when an ODR sync signal is received, the ODR generator module 228 may respond by immediately acquiring and storing the second sensor data before the ODR generator module 228 would normally have done so (albeit subject to some delay which will be discussed herein).

The synchronization process may be performed as needed. For example, the processing circuit 210 may generate the ODR-Sync signal, outputting such signal at the sync signal output 214, when an application begins executing in which a relatively high degree of synchronization between various sensors is desirable. For example, upon initiation of a camera application, a relatively high degree of synchronization between an image sensor and a gyroscope may be beneficial (e.g., for Optical Image Stabilization (OIS) or Electronic Image Stabilization (EIS) operation). The processing circuit 210 may, for example, generate the ODR-Sync signal when a camera application is initiated (e.g., under the direction of a host operation system, under the direction of the application, etc.). Also for example, the desire for such synchronization may occur during execution of an application, for example when the application is about to perform an activity for which a relatively high degree of synchronization is desirable. For example, when a focus button is triggered for a camera application or a user input is provided to the camera application indicating that the taking of a photo is imminent, the processing circuit 210 may generate the ODR-Sync signal.

The processing circuit 210 may occasionally (e.g., periodically) perform the sync process as needed, for example based on a predetermined re-sync rate. Also for example, the processing circuit 210, having knowledge of the stability (or drift) of the internal ODR signal of the sensor circuit 220 and/or having knowledge of the desired degree of synchronization, may intelligently determine when to generate the ODR-Sync signal. For example, if a worse case drift for the internal ODR signal of the sensor circuit 220 accumulates to an unacceptable degree of misalignment every T amount of time, the processing circuit 210 can output the ODR-Sync signal to the sensor circuit 220 at a period less than T. Such re-synchronization may, for example, occur continually, while a particular application is running, when a user input has been detected that indicates recent or present use of an application in which synchronization is important, when a user input indicates that a function of the system 200 requiring enhanced sensor synchronization is imminent, when use of the host device is detected, etc.

As an example, a time alignment uncertainty may be expressed as illustrated below in Equation 1.

Uncertainty=(Sensor System ODR ppm/sec drift)/(ODR−Sync frequency) Eq. 1

Thus, as the ODR-Sync frequency increases, the alignment uncertainty decreases. The energy and processing costs, however, may generally rise with increasing ODR-Sync frequency.

Note that different applications may have different respective synchronization requirements. Thus, first and second applications may cause generation of the ODR-Sync signal at different respective rates. Even within a particular application, the ODR-Sync signal may be generated at different rates (e.g., during normal camera operation versus telephoto operation, during operation with a relatively steady user versus a relatively shaky user where the degree of steadiness can be detected in real time, etc.).

The processing circuit 210 may also, for example, determine when the synchronizing activity is no longer needed. For example, upon a camera or other image acquisition application closing, the processing circuit 210 may determine that the increased (or enhanced) amount of synchronization is no longer necessary. At this point, the sensor circuit 220 timing may revert to the autonomous control of the RC oscillator module 222. Also for example, after a health-related application that determines a user's vital signs finishes performing a heart monitoring activity, the processing circuit 210 may discontinue generating ODR-Sync signals. Further for example, after a photograph has been taken using a camera application and no user input has been received for a threshold amount of time, the camera application may direct the processing circuit 210 (e.g., with software instructions) to discontinue generating ODR-Sync signals. Still further for example, during execution of a navigation application, for example during an indoor navigation and/or other navigation that relies on on-board sensors like inertial sensors, the processing circuit may generate the ODR-Sync signals as needed, but may then, for example, discontinue such generation when GPS-based navigation takes over.

As mentioned herein for example in the discussion of FIG. 2, in accordance with various aspects of this disclosure, the sensor circuit 220 may comprise an external clock input 234 for an external clock signal. In an example configuration, the output from the RC Oscillator Module 222 and the external clock input 234 may both be input to a multiplexer 223, and the desired clock may be selected for utilization by the sensor circuit 220. For example, the sensor circuit 220 may select the external clock signal for utilization whenever present (e.g., with energy detection circuitry coupled to the external clock input 234), the sensor circuit 220 may select the external clock signal for utilization only when directed to do so by the processing circuit 210 (e.g., under the control of an operating system and/or operation specific application being executed by the processing circuit 210), etc. Also for example, the processing circuit 210 may direct the sensor circuit 220 to utilize the external clock signal when the processing circuit 210 is generating ODR-Sync signals.

For example, an external clock signal, for example a system or host clock, may be substantially more accurate than the internal clock of the sensor circuit 220. In such a scenario, utilization of a relatively more accurate external clock for controlling the internal ODR signal may advantageously reduce the rate or frequency at which the processing circuit 210 generates the ODR-Sync signal. In other words, if the sensor circuit 220 internal ODR signal is not drifting as much, it does not need to be re-synchronized as often.

It should be noted that though the above discussion focused on one sensor circuit, the scope of this disclosure is not limited to any particular number of sensor circuits. For example, any number of sensor circuits may be incorporated. In an implementation involving a plurality of sensor circuits, each sensor circuit may have respective synchronization requirements. For example, in such a scenario, all of the sensor circuits may share a synchronization input, which may for example be designed to synchronize the sensor circuit that is in the greatest need of synchronization.

Also for example, in such a scenario each sensor may have a dedicated line (or address on a shared bus) that is used to individually synchronize the sensor in accordance with its own needs. In such a manner, unnecessary synchronization of sensors that are not in need of such synchronization may be avoided. In an example scenario in which a plurality of sensors share a common sync line, the processing circuit 210 may determine an ODR-Sync pulse rate based on a worst case internal ODR drift rate for the sensor circuits. For example, a first sensor circuit may have the highest Internal ODR drift rate. In such a scenario, the processing circuit 210 may determine the ODR-Sync pulse frequency for all of the sensor circuits based on the Internal ODR drift rate of only the first sensor circuit. In another example scenario, the processing circuit 210 may determine an ODR-Sync pulse rate also based on the real time needs of an application currently being executed. For example, if a particular sensor with a worst respective internal ODR drift rate is not being utilized by the current application, then the processing circuit 210 need not consider such processor when determining when to generate the ODR-Sync pulse (e.g., a frequency thereof).

Referring to FIG. 4, such figure shows a timing diagram 400 of an example synchronization scenario, in accordance with various aspects of the present disclosure. The top line, labeled “Fast Clock” illustrates a fast clock signal, such as for example may be output from the fast clock generator module 224. The fast clock signal may, for example, be based on an external clock received at the external clock input 234 of the sensor circuit 220. The middle time line, labeled “Internal ODR” represents the internal ODR signal of the sensor circuit 220. The internal ODR signal may, for example, be synchronized to the fast clock signal. The internal ODR signal may, for example, be the same as the internal ODR signal shown in FIG. 3. The bottom time line, labeled “ODR-Sync” illustrates a sync signal (e.g., the ODR-Sync signal output from the sync signal output 214 of the processing circuit 210). The ODR-Sync signal may, for example, be the same as the ODR-Sync signal shown in FIG. 3.

Though not illustrated in FIG. 3, synchronizing the internal ODR signal to the ODR-Sync signal might take one or more clock cycles. An example of this is illustrated in FIG. 4, for example in the region labeled 430. For example, there may be some delay between the rising edge of the ODR-Sync pulse and the next synchronized internal ODR pulse. For example, after a previous internal ODR event 423 (e.g., a clock event), the processor circuit 210 outputs an ODR-Sync signal 425 from the sync signal output 214 to the sensor circuit 220. The sensor circuit 220 may, for example, notice or clock in the ODR-Sync pulse at rising edge 441 of the Fast Clock. The next internal ODR event 425 (e.g., a clock event, sensor data storage event, etc.) may then occur at the next rising edge 442 of the Fast Clock. Note that the one or more cycles of the Fast Clock may be necessary before generation of the next internal ODR event 425, depending on the particular implementation.

In general, the faster (or higher frequency) that the fast clock signal is, the closer in time the synchronized internal ODR pulse will be to the rising edge of the ODR-Sync pulse. For example, the rate of the fast clock signal may be specified to result in less than some maximum acceptable delay (e.g., 1 ms, 1 us, less than 1 us, etc.).

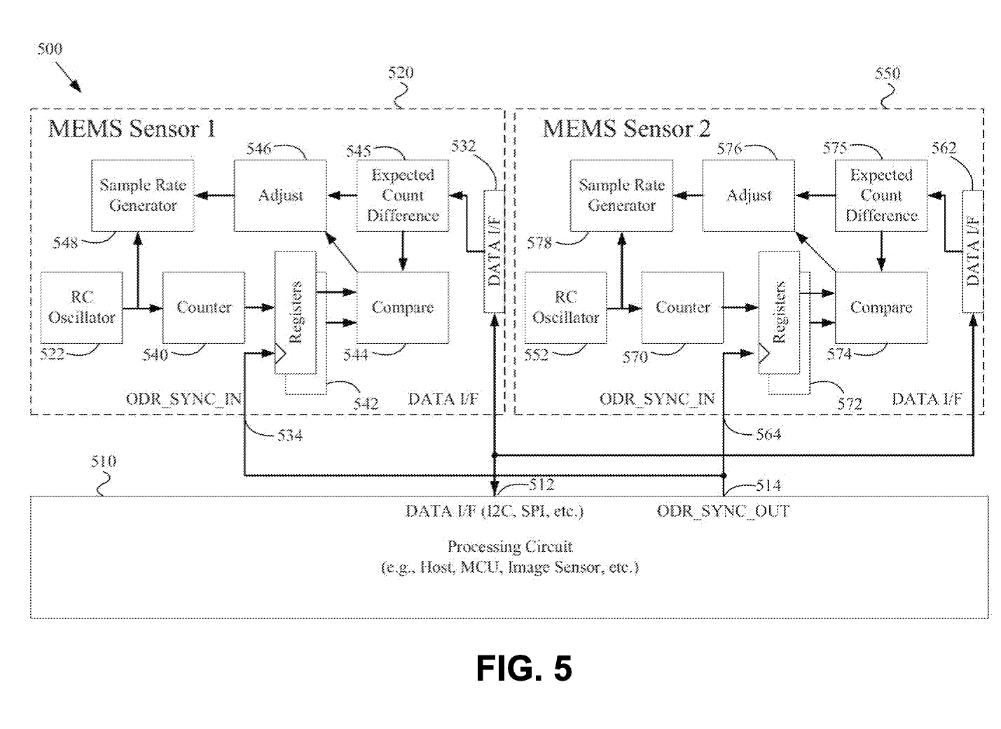

Referring now to FIG. 5, shows an example sensor system 500, in accordance with various aspects of the present disclosure. The example sensor system 500 may, for example, share any or all characteristics with the example systems 100 and 200 shown in FIGS. 1 and 2 and discussed herein, and all sensor systems discussed herein. For example, the aspects of the example sensor system 500 shown in FIG. 5 may be readily incorporated into the systems 100 and 200 shown in FIGS. 1 and 2, and/or any system discussed herein, and vice versa. Note that, for illustrative clarity, various modules of other systems discussed herein are not shown in the diagram illustrated in FIG. 5 (e.g., the MEMS analog module 225, sample chain module 226, output data storage module 230, etc.).

The components of the sensor system 500 shown in FIG. 5 may share any or all characteristics with similarly-named components of FIGS. 1 and 2. For example, the processing circuit 510 of FIG. 5 may share any or all characteristics with the processing circuitry of FIG. 1 (e.g., the application processor 110 and/or sensor processor 130), the processing circuit 210 of FIG. 2, any processing circuit discussed herein, etc. Also for example, the first and second sensor circuits 520 and 550 of FIG. 5 may share any or all characteristics with the sensor circuits 115 and 150 of FIG. 1, the first and second sensor circuits 220 and 250 of FIG. 2, any sensor circuit discussed herein, etc.

In general, the processing circuit 510 may generate a series of sync pulses (e.g., ODR-Sync pulses) at an accurate and consistent frequency and/or period that is known by the first sensor circuit 520, which are then communicated to the first sensor circuit 520 (e.g., output at the sync signal output 514). The first sensor circuit 520 may then compare its internal clock frequency to that of the known ODR-Sync frequency. Once the first sensor circuit 520 knows the error associated with its internal clock, the first sensor circuit 520 can then adjust its internal timing (e.g., by scaling the internal clock to its desired frequency, by scaling the divide value used to create the ODR, etc.) such that it more accurately matches the desired ODR. This process may be performed with one or more sensor circuits, for example independently.

For example, the output of the RC oscillator module 522 may be provided to a counter module 540. In an example scenario, upon arrival of a first ODR-Sync pulse from the processing circuit 510, the value of a counter may be stored in a first register of a register bank 542. Continuing the example scenario, upon arrival of a second ODR-Sync pulse from the processing circuit 510, the value of the counter may be stored in a second register of the register bank 542. The compare module 544 may then compare the difference between the first and second stored counter values to an expected count difference value, for example received from the expected count difference module 545, that would have resulted had the RC oscillator module 522 been operating ideally. The results of the comparison may then be output to the adjust module 546.

The adjust module 546 may then, for example, determine an adjustment, for example to a clock frequency and/or a clock divide-by value, to achieve a desired internal timing adjustment (e.g., of the Internal ODR signal) for the first sensor circuit 520. The adjust module 546 may then communicate information of the determined adjustment to the sample rate generator module 548. Note that information of the ODR-Sync pulse spacing and/or expected count difference value may be communicated to the first sensor circuit 520 via the data interface 512 of the processing circuit 510 and via the data interface 532 of the first sensor circuit 520. Such information may also, for example, comprise frequency information.

In an example scenario, if the ideal difference between the counters should have been 100, but was only 99, then such a discrepancy could be corrected, for example by changing a clock divide-by value, changing a value of a variable resistor and/or variable capacitor in a timer circuit, etc.

As discussed above with regard to the example system 200 illustrated in FIG. 2, the processing circuit 510 may determine when to perform the synchronization discussed herein and, for example, communicate to the sensor circuits 520 and 550 whether to perform the synchronization. Also for example, the sensor circuits 520 and 550 may also determine whether to perform the synchronization. As discussed herein, intelligently determining when to perform enhanced synchronization, for example different from normal operation, may beneficially save energy by eliminating unnecessary communication and/or processing.

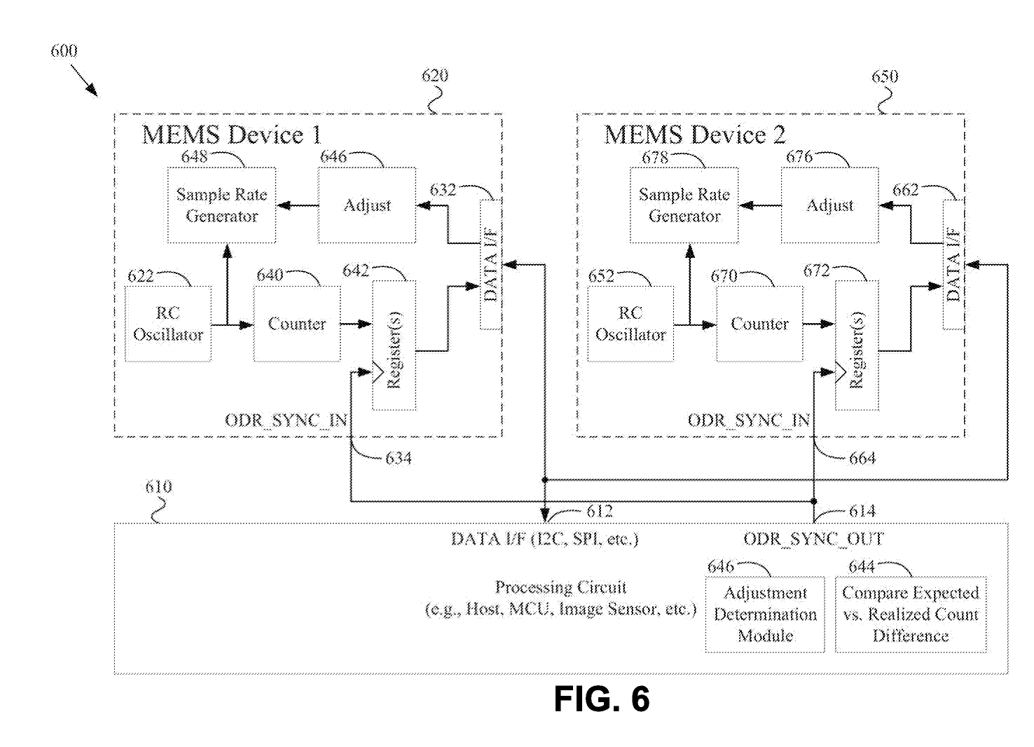

Referring now to FIG. 6, such figure shows an example sensor system 600, in accordance with various aspects of the present disclosure. The example sensor system 600 in FIG. 6 may, for example, share any or all characteristics with the example systems 100, 200, and 500 shown in FIGS. 1, 2, and 5, and discussed herein. For example, the aspects of the example sensor system 600 shown in FIG. 6 may be readily incorporated into the systems 100, 200, and 500 shown in FIGS. 1, 2, and 5, and vice versa. Note that, for illustrative clarity, various modules of other systems discussed herein are not shown in the diagram illustrated in FIG. 5 (e.g., the MEMS analog module 225, sample chain module 226, output data storage module 230, etc.).

The components of the sensor system 600 shown in FIG. 6 may share any or all characteristics with similarly-named components 100, 200, and 500 of FIGS. 1, 2 and 5. For example, the processing circuit 610 of FIG. 6 may share any or all characteristics with the processing circuitry of FIG. 1 (e.g., the application processor 110 and/or sensor processor 130), of FIG. 1, the processing circuit 210 of FIG. 2, and the processing circuit 510 of FIG. 5, any processing circuit discussed herein, etc. Also for example, the first and second sensor circuits 620 and 650 of FIG. 6 may share any or all characteristics with the sensor circuits 115 and/or 150 of FIG. 1, the first and second sensor circuits 220 and 250 of FIG. 2, the first and second sensor circuits 520 and 550 of FIG. 5, any sensor circuit discussed herein, etc.

The sensor system 600 shown in FIG. 6 may, for example, generally differ from the sensor system 500 shown in FIG. 5 in that the processing circuit 610 plays a relatively more prominent role in adjusting the internal clock rate of the sensor circuits 620 and 650.

In general, the processing circuit 610 may generate two or more ODR-Sync pulses spaced sufficiently enough apart so that the processing circuit 610 can read an internal register 642 in the sensor circuit 620, for example via the data interface 632, between each of the pulses. The processing circuit 610 may, for example, output such ODR-Sync pulses from the sync signal output 614. For example, each ODR-Sync pulse may cause the sensor circuit 620 to capture its own internal timer value in a register 642 accessible to the processing circuit 610 via the data interface 632. Knowing the period of time between each of the pulses sent to the sensor circuit 620 and the corresponding stored (e.g., latched) internal timer counts, the processing circuit 610 may then estimate the clock error of the sensor circuit 620. The processing circuit 610 may then use this error estimate to program the sensor circuit ODR so that it is more in line with the desired rate. This process may be performed with one or more sensor circuits (e.g., first sensor circuit 620, second sensor circuit 650, etc.), for example independently.

In an example scenario, if the desired ODR of the sensor circuit 620 is 100 Hz, and the estimated clock error is +1%, the processing circuit 610 may program the ODR for the sensor circuit 620 to 99 Hz to give the sensor circuit 620 an effective ODR of or near 100 Hz. This estimation process may be repeated on a scheduled basis or when operational conditions warrant (e.g., based on temperature and/or other operational parameters of the sensor circuit 620 changing by more than a specified threshold).

For example, the output of the RC oscillator module 622 may be provided to a counter module 640. Upon arrival of a first ODR-Sync pulse from the processing circuit 610 (e.g., at the sync signal input 634), a first counter value of the counter module 640 may be stored in a register 642. Before generation of a second ODR-Sync pulse, the processing circuit 610 may read the stored first counter value from the register 642, for example via the data interface 632 of the sensor circuit 620 and the data interface 612 of the processing circuit 610. Upon arrival of the second ODR-Sync pulse from the processing circuit 610, a second counter value of the counter module 640 may be stored in the register 642 (or, for example, a second register in a scenario in which both counters are read out after both ODS-Sync pulses have been generated). The compare module 644 of the processing circuit 610 may then compare the difference between the first and second counter values to an expected difference value that would have resulted had the RC oscillator module 622 been operating ideally. The adjustment determination module 646 of the processing circuit 610 may then, for example, determine an adjustment to, for example, a clock frequency and/or a divide-by value of the sensor circuit 220 to achieve a desired internal timing adjustment (e.g., of the Internal ODR signal) for the sensor circuit 220. The adjustment determination module 646 of the processing circuit 610 may then communicate information of the desired timing adjustment (e.g., an adjustment in a requested ODR) to the adjust module 646 of the sensor circuit 620 via the data interface 632 of the sensor circuit 620 (e.g., via a data bus, for example an I2C or SPI bus).

The example sensor systems discussed herein, for example, comprise a sensor circuit 620 with a sync signal input 634. It should be noted that the sync signal input 634 may be implemented on a shared integrated circuit pin, for example an integrated circuit pin that may be utilized for a plurality of different sync signals. For example, a single integrated circuit pin may be configurable to receive an ODR_SYNC_IN input signal and/or an F-SYNC input signal. For example, in system in which it is desired to utilize the example ODR_SYNC_IN-based functionality discussed herein, the sensor circuit 620 may be programmed, for example at system initialization and/or at system construction, to utilize the shared pin as the ODR_SYNC_IN pin. Also for example, in a system in which it is desired to utilize legacy F-SYNC-based synchronization, the sensor circuit 620 may be programmed to utilize the shared pin as an F-SYNC pin. Such a system may, for example, tag the next sample following receipt of an F-SYNC signal.

The example systems 100, 200, 500, and 600 illustrated in FIGS. 1, 2, 5, and 6, and discussed herein, were presented to illustrate various aspects of the disclosure. Any of the systems presented herein may share any or all characteristics with any of the other systems presented herein. Additionally, it should be understood that the various modules were separated out for the purpose of illustrative clarity, and that the scope of various aspects of this disclosure should not be limited by arbitrary boundaries between modules. For example, any one or more of the modules may share hardware and/or software with any one or more other modules.

As discussed herein, any one or more of the modules and/or functions discussed herein may be implemented by a pure hardware solution or by a processor (e.g., an application or host processor, a sensor processor, etc.) executing software instructions. Similarly, other embodiments may comprise or provide a non-transitory computer readable medium and/or storage medium, and/or a non-transitory machine readable medium and/or storage medium, having stored thereon, a machine code and/or a computer program having at least one code section executable by a machine and/or a computer (or processor), thereby causing the machine and/or computer to perform the methods as described herein.

### Section 3: Gyroscope and Image Sensor Synchronization

In the discussions above, the synchronization of MEMS sensor has been discussed in a more general manner, without going into specific details about any particular type of sensor or any specific type of application. In this section we will focus on the synchronization between a motion sensor, in these examples a gyroscope, and an image sensor. This motion-image synchronization is important to image stabilization systems in order to remove unwanted motion related artifacts from still images and video streams. It should be appreciated that these synchronization techniques can be similarly implemented with other sensors, besides gyroscopes, that are discussed herein.

FIG. 7 shows a high-level block diagram of a gyroscope 151 in accordance with various aspects of the present disclosure. Gyroscope 151 includes an input 710 and at least one output 720. Gyroscope 151 may represent one of the MEMS sensors depicted and described in detail in FIGS. 2, 5, and 6, where FIG. 7 depicts simplified version of these MEMs devices without showing all the components. In some embodiments, input 710 may be similar to e.g. ODR_SYNC_IN 234/534/634, output 720 may be similar to e.g. DATA I/F 232/532/632, and logic 730 represent sensor processor 130 or may be other dedicated logic required for the functionalities described below. In the absence of other internal sensors 150, gyroscope 151 may represent MPU 120 (shown in dashed line), where logic 730 (shown in dashed line in side MPU 120) is represented by sensor processor 130 or other logic of MPU 120. Thus, while logic 730 is depicted within gyroscope 151, it may in fact be implemented external to gyroscope 151 in sensor processor 130 or in some other portion of MPU 120. Similarly, input 710 and output 720 may be separate dedicated communication lines of MPU 120 or may be part of communication bus 105.

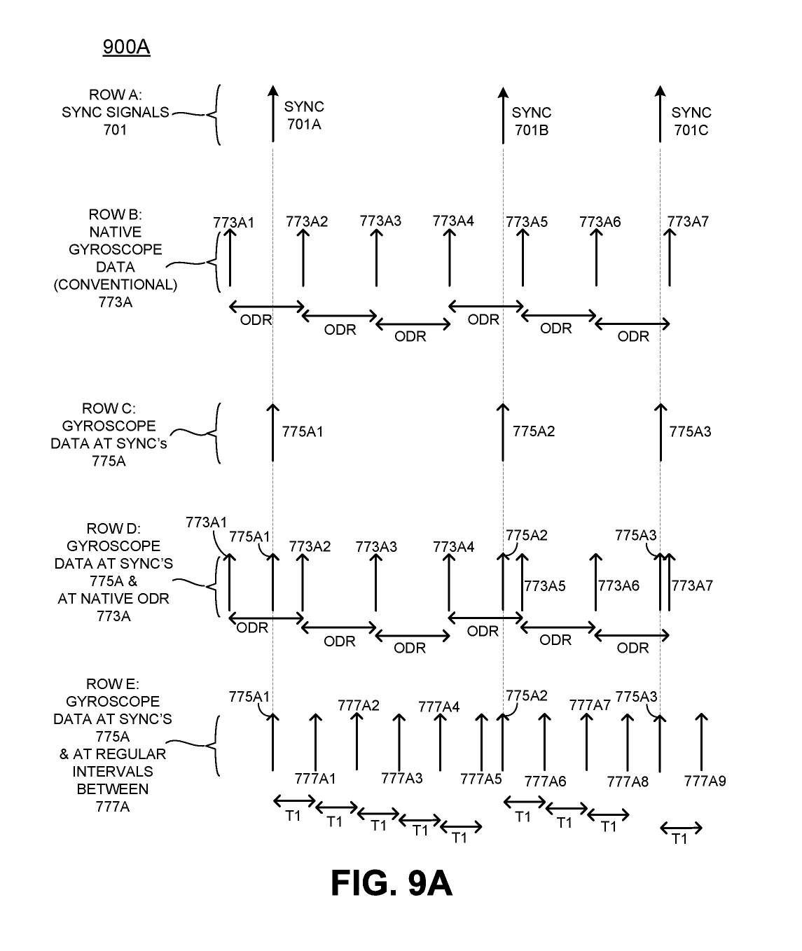

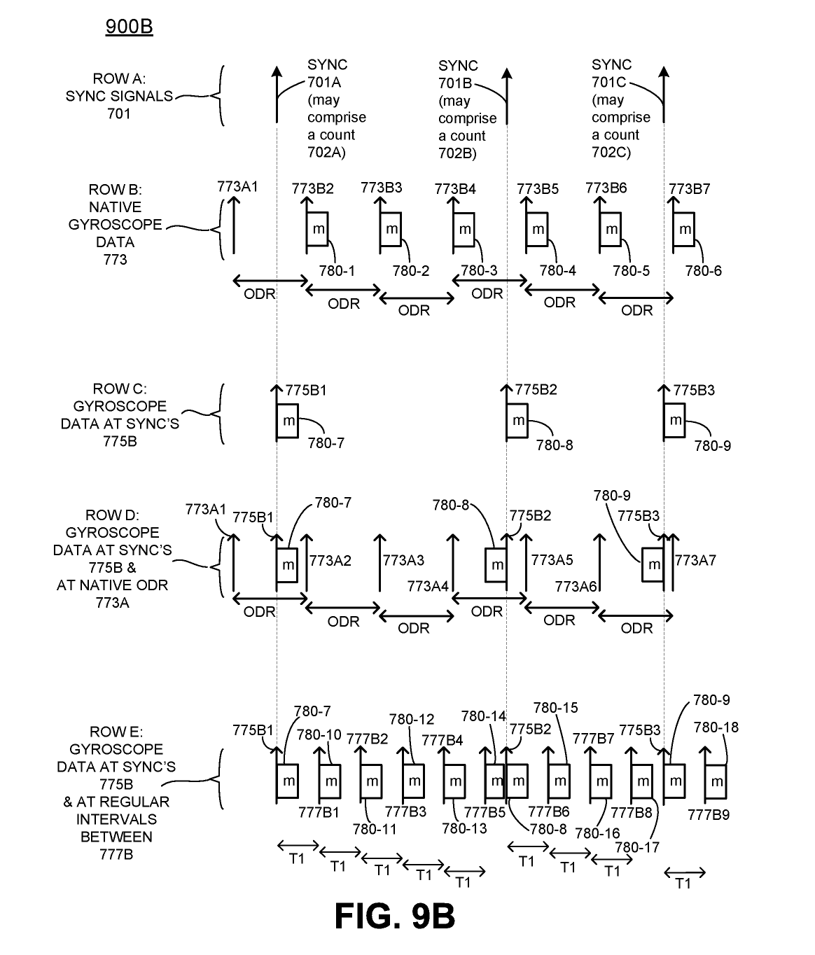

Gyroscope 151 measures angular velocities on one or more orthogonal axes of rotation of device 100 (and consequently of image sensor 118 which is disposed in device 100). These angular velocities are output as all or a portion of gyroscope data 770 and are used to help EIS system 117 determine the motion of device 100 and the image sensor 188 during the image capture process. For example, based on the motion information a displacement vector may be determined that corresponds to the motion of image sensor 118 from one portion of an image capture to the next (e.g., from frame to frame, from line to line, etc.). In one aspect, a gyroscope 151 may each have three orthogonal axes, such as to measure the motion of device 100 with three degrees of freedom. Gyroscope data 770 (e.g., 773, 775, 777 in FIGS. 9A and 9B) from gyroscope 151 may be combined in a sensor fusion operation performed by sensor processor 130 or other processing resources of device 100 with e.g. a 3-axis accelerometer in order to provide a six axis determination of motion. Gyroscope data 770 may be converted, for example, into an orientation, a change of orientation, a rotational velocity, a rotational acceleration, etc. The information may be deduced (captured, extrapolated, interpolated, etc.) for one or more predefined axes, depending on the requirements of a sensor client. Gyroscope data 770 may be buffered in an internal memory of gyroscope 151, in internal memory 140, or in another buffer prior to delivery to EIS system 117. In some embodiments gyroscope 151 may be implemented using a micro-electro-mechanical system (MEMS) that is integrated with sensor processor 130 and one or more other components of MPU 120 in a single chip or package. It should be appreciated that, conventionally, a gyroscope 151 measures and outputs gyroscope data 770 at a native Output Data Rate (ODR), as described in relation to FIG. 2. The gyroscope data 770 often comprises measurements that are captured and output at this native ODR.

Input 710 is used, at least in part, for receiving synchronization signals 701 (that may include counts 702) from an external source such as image sensor 118. The synchronization signal is associated with the capture of a portion of an image frame by image sensor 118. The portion may be an entire image frame or some sub-portion that is less than an entire image frame.

An output 720 (e.g., 720A, 720B, and the like) is used, at least in part, for outputting gyroscope data 770 (that may include one or more of a gyroscope measurement prompted by and a message 780 that is generated by logic 730) for use in the stabilization of a portion of an image frame. In some embodiments, for example, output 720A may output gyroscope data 770 that is supplemented by a message 780 (described below) while output 720B outputs the message 780 alone. In some embodiments, for example, output 720A may output gyroscope data 770 that is not supplemented by a message 780 while output 720B outputs the message 780 alone. In some embodiments, gyroscope 151 includes only a single output 720 (e.g., 720A) that is used for output of gyroscope data 770 that may or may not be supplemented by a message 780. It is appreciated that in some embodiments, the gyroscope data 770 (with or without message 780), the message 780, or both may be received by image sensor 118, EIS system 117, a buffer, or some other portion of device 100.

Logic 730 may be implemented as hardware, or a combination of hardware with firmware and/or software. Logic 730 may represent sensor processor 130 or other logic within motion processing unit 120. Logic 730 operates to prompt the generation and output from gyroscope 151, gyroscope data 770 that is substantially synchronized in time with the receipt of the synchronization signal 701. By “substantially” what is meant is that the output is generated as fast as the gyroscope 151 and any processing and/or signal propagation delays allow (as discussed in relation to FIG. 4). In some embodiments, in response to the receipt of a synchronization signal, logic 730 operates to cause gyroscope 151 to capture a gyroscope measurement that is then output as gyroscope data 770. In some embodiments, in response to the receipt of a synchronization signal, logic 730 operates to extrapolate a synthetic gyroscope measurement from a previous measurement at the native output data rate and then output this synthetic extrapolated measurement as gyroscope data 770. In some embodiments, in response to the receipt of a synchronization signal, logic 730 operates to interpolate a synthetic gyroscope measurement between two consecutive measurements at the ODR and then output the synthetic interpolated measurement as gyroscope data 770.

Logic 730, may additionally or alternatively enable the output, from gyroscope 151, of gyroscope data 770 at the native ODR in response to receipt of a synchronization signal 701. The enablement of ODR gyroscope outputs may occur after the output of gyroscope data 770 that occurs in response to (i.e., in time synchronization with) the synchronization signal 701 and may be for a limited period of time.

In some embodiments, logic 730 operates to compile a message 780 (shown as a boxed “m” in FIG. 9B) that may be output separate from or as a portion of gyroscope data 770. This message may include, without limitation, one or more of: an internal count, an external count, and timing information (e.g., an elapsed time since the last receipt of a synchronization signal 701, a time of receipt of the synchronization signal 701). An internal count may be a count generated in gyroscope 151 (or MPU 120), and an external count may be a count supplied to the gyroscope 151 and generated by e.g. the image sensor 118 or camera unit 116. In some embodiments a message associated with the synchronization signal is generated in response to receipt of synchronization signal 701.

In some embodiments, logic 730 may maintain an internal count that is incremented with each output of gyroscope data 770. This internal count may be used to supplement the gyroscope data 770, such as by including it as a portion of the gyroscope data 770 (i.e., a gyroscope measurement plus a message with the internal count) or may be output separately from the gyroscope data 770. The count number of this internal count can thus be used, such as by EIS system 117, to ensure utilization of gyroscope data 770 in proper sequence by causing gyroscope measurements to be used in order of their supplemented internal count number. Moreover, counts can be used to make sure to linked the correct motion data with the corresponding image data. For example, if some of the image data or motion data gets lost, when the image data and motion data reach the EIS system 117 in sequence, but with one or more image or motion sample missing, the wrong motion data is linked with the image data.

The internal count may represent a frame count, where the internal count is increased when a frame sync signal is received from the image sensor 118. The image sensor may have its own internal counter and send out Frame sync signal at each new frame. In this case, the internal count from the image sensor and the internal count in the gyroscope may be different, but may increase at the same rate. The internal count of the gyroscope may be reset by the gyroscope, or may be reset by a special sync signal or command from e.g. the image sensor. For example, the internal count may be reset each time an application is started that uses some form of image stabilization. Although FIG. 7 shows only one input, gyroscope 151 may have more than one input, for example, one input dedicate for frame sync signal coming from the image sensor, and an additional input for line sync signal coming from the image sensor. Alternatively, the same input may be used for the different type of sync signals.

In some embodiments, logic 730 may receive an external count 702, as part of the received synchronization signal 701. This external count may be used to supplement the gyroscope data 770, such as by including it as a portion of the gyroscope data 770 (i.e., a gyroscope measurement plus a message with the external count) or may be output separately from the gyroscope data 770. It should be appreciated that the image sensor 118 also associates this count with a portion of a captured image, such as a full frame, a portion of a frame that is more than a line and less than a full frame, a line of an image frame, or a portion of an image that is less than a line of an image frame. The count number of this external count can thus be used, such as by EIS system 117, to match the associated portion of the captured image with gyroscope data 770 that is supplemented with the same external count number. The external count may also be used to set the internal count, for example at initialization, after which the external count is no longer required but the sync signal can be used to keep the internal count identical to the counter of the e.g., image sensor. A periodic communication of the external count can be used to verify if the internal count is still correct.

In some embodiments, logic 730 measures time elapsed from an event, such as elapsed time since last receipt of a synchronization signal 701. Logic 730 may, for example, use any of the clocks discussed in relation to FIG. 2 to measure the time. When a gyroscope measurement is captured the elapsed time is noted and associated with the measurement and is used to supplement the gyroscope data 770 that includes the measurement (such as by including a message with the elapsed time information). In some embodiments, the measurement of a predetermined amount of elapsed time (e.g., 1 ms, 5 ms, 10 ms, etc.) can be used by logic 730 to trigger generation of a gyroscope measurement (either a captured, interpolated, or extrapolated measurement) and output of the triggered measurement as gyroscope data 770. This can occur at defined intervals such as every 1 ms, every 5 ms, every 10 ms, etc. measured from the last receipt of a synchronization signal 701, measured from the last output of gyroscope data 770, or measured from some other event. When gyroscope data 770 is supplemented with a message that indicates the amount of elapsed time, this allows EIS system 117 to ensure utilization of gyroscope data 770 in proper sequence and also provides regularly spaced gyroscope measurements for use by EIS system 117. For example, logic 130 can measure the time elapsed between an incoming frame sync signal and a captures gyroscope sample. This information may then be send as a message to EIS 117, which may use the timing information to determine the correct motion data with the image data, for example through interpolation or extrapolation of the data.

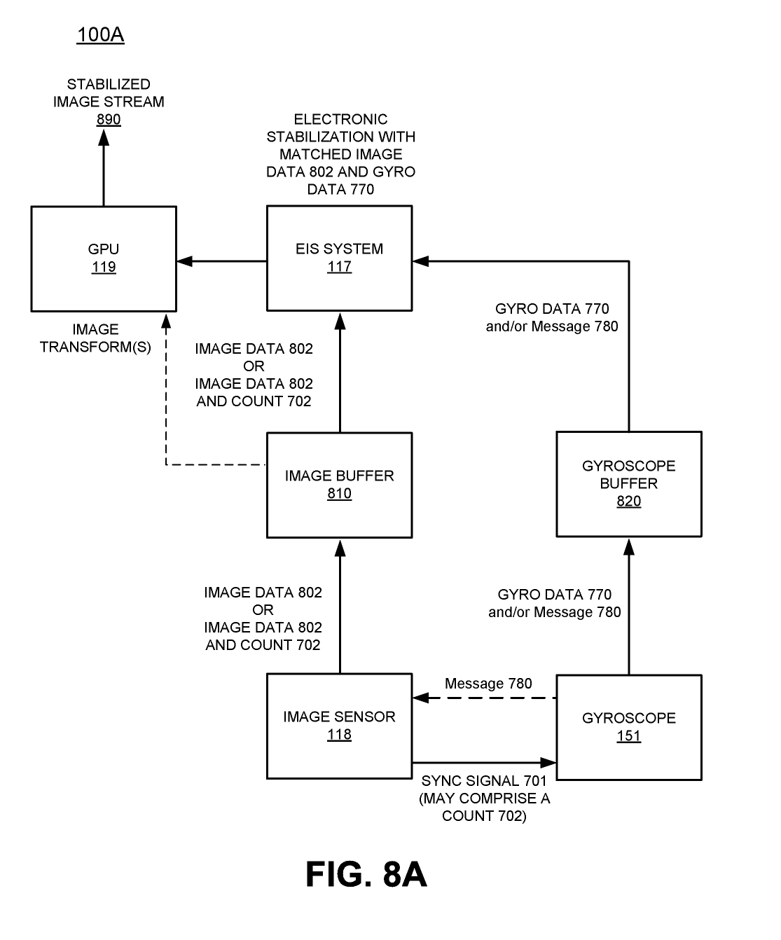

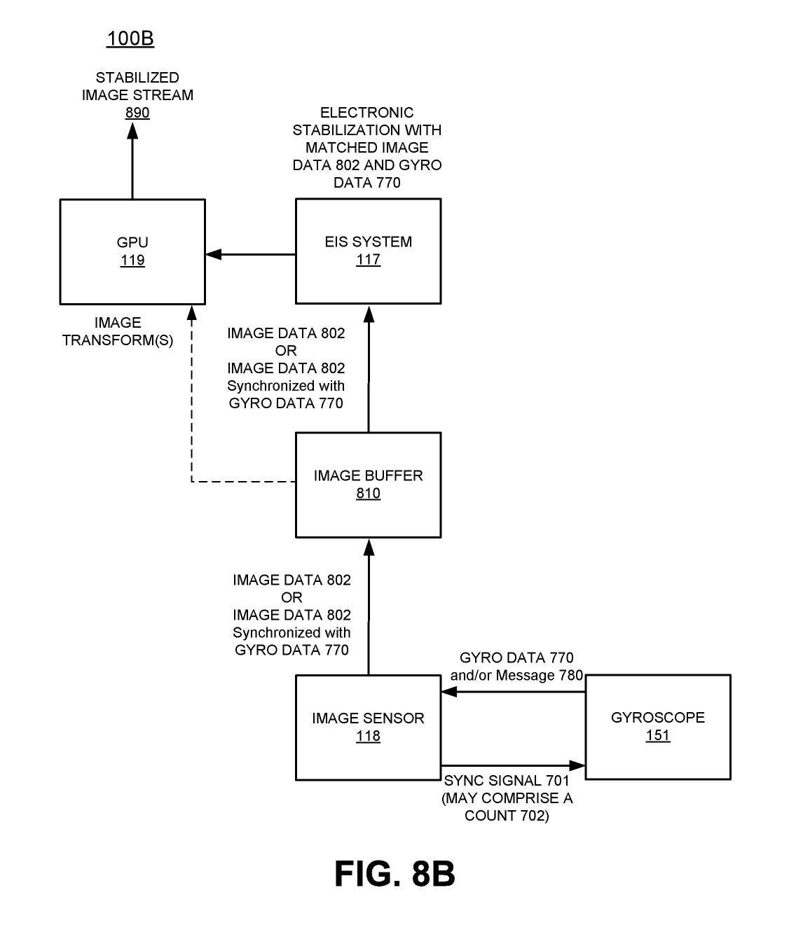

FIG. 8A shows signal flow paths with respect to a block diagram of a portion of an example device 100A, in accordance with various aspects of the present disclosure. Device 100A may include some or all of the components of device 100. FIG. 8A depicts an image sensor 118, a gyroscope 151, an image buffer 810, a gyroscope buffer 820, an EIS system 117, and a graphics processing unit 119. Device 100A may be any type of device capable of capturing an image with an image sensor 118, and where the image capturing process may be perturbed or otherwise influenced by motion of device 100A. For example, device 100A may be a handheld device, where the motion of device 100A is caused by the user, either intentionally or unintentionally, e.g., vibrations of device 100A due to shaking of the hands of the user. In another example, the image sensor 118 or device 100A may be attached to, or incorporated in, another device or object, such as e.g., a camera unit 118 in or on a car or other moving object.

Image buffer 810 may be implemented in a memory of camera unit 116, in application memory 111, in internal memory 140, or in some other memory of device 100.

Gyroscope buffer 820 may be implemented in a memory of camera unit 116, in a memory of image sensor 118, in application memory 111, in internal memory 140, or in some other memory of device 100.

In some embodiments, the outputs of the image data 802 and gyroscope data 770 are buffered in image buffer 810, gyroscope buffer 820, or the like. This buffering may be required, in some embodiments, for the synchronization process employed by EIS System 117 to find the matching image and gyroscope data, for example in case there is a delay on one of the sides. The buffering also allows for accumulation of image data 802 for filtering or any other type of processing that requires a minimum amount of image data to carry out. The buffering allows EIS system 117 additional time to determine the stabilization parameters, for example, for the computation and prediction of the position of the images portions with respect to each other. The buffing of gyroscope data 770 also allows EIS system 117 to switch between different strategies on image stabilization (smoothing, and others).

An image frame is composed of a plurality of lines of image data. For all the image stabilization and processing methods discussed below, it is important that the motion data of the device corresponds as closely as possible to the moment image data is captured when it is used to correct motion of the image sensor that may affect that particular image data. Thus the methods attempt to determine motion data at the moment of image frame (or portion thereof) acquisition or substantially at the moment (i.e., as close to the moment as is feasible given delays introduced by signal propagation and/or processing delays, and yet not far enough from the moment that context is lost). This allows for good correlation between the motion data that is used by an EIS or OIS to stabilize the acquired image data. The motion may be determined per image frame, meaning that for example the average velocity and direction of the device is calculated per frame. If more precision is required, the motion may be determined per sub section of each image frame, per line of the image frame, or per portion of the line of the image frame. The linking of the motion data and the image data division depends on the amount of precision required for the image processing, and the accuracy that is possible in the timing of the motion calculation and the image sections. In other words, the level of synchronization between the motion data and image data depends on the required and possible accuracy.

The motion of the device 100A may be determined using different types of sensors and techniques. For example, MEMS type motion sensors, such as e.g., accelerometer 153 and/or gyroscope 151 may be used. In another example, the motion of the device may be determined using techniques based on light or other electromagnetic waves, such as e.g., LIDAR. In the remainder of the disclosure a gyroscope sensor (gyroscope 151) is used as an example motion sensor. However, it should be appreciated that other motion sensors may be similarly employed.

The synchronization of the image data 802 and the gyroscope data 770 may be performed using different methods. If the timing characteristics of the architecture are known, the image sensor 118 and the gyroscope 151 may output their respective data (802 and 770) to the EIS system 117 (or processor thereof) performing the image processing, and the synchronization will be conducted based on the timing characteristics of or associated with the data. Although depicted as graphics processing unit 119 in FIGS. 8A and 8B, the EIS processor may be application processor 110, graphics processing unit 119, sensor processor 130, or any other suitable processor of device 100. However, any timing problems, such as delays or dropped image data 802 or gyroscope data 770, will lead to problems and may results in incorrectly synchronized or unsynchronized data.

In one embodiment, the synchronization may be performed by time stamping the image data 802 and the gyroscope data 770. The image sensor 118 may timestamp each frame, frame segment, each line, or each sub-portion of a line of image data 802. The timestamp data may be incorporated in the image data 802, or may be provided separately. The gyroscope 151 may timestamp each data sample output as a gyroscope data 770. The EIS system, and its processor, may then synchronize the image data 802 and gyroscope data 770 by matching the timestamps. The gyroscope data 770 with the timestamp closest to the timestamp of the image data 802 may be utilized; the gyroscope data 770 with a gyroscope measurement prior to the timestamp of the image data 802 may be extrapolated to the time of the image data timestamp; or gyroscope data 770 with a time of measurement prior to the image data timestamp and gyroscope data 770 with a measurement time subsequent to the image data timestamp may be or interpolated to match the exact time of the timestamp of the image data 802.

In one embodiment, the synchronization may be performed by using synchronization signals between the image sensor and the gyroscope sensor. For example, the image sensor may output a synchronization signal 701 coincident with every image frame capture or with capture of some sub-portion of an image frame. Gyroscope 151 may then use this synchronization signal 701 to synchronize the gyroscope data's measurement or generation, and subsequent output as gyroscope data 770 to the image data 802 of the image frame or portion thereof that is associated with the synchronization signal 701.

With continued reference to FIG. 8A in one embodiment image data 802 for a portion of an image frame is captured by image sensor 118. Image sensor 118 generates a synchronization signal 701 that is time synchronized with the image data 802 and outputs the synchronization signal 701 which is then received by gyroscope 151 via input 710 of gyroscope 151. Logic 730 of gyroscope 151 causes gyroscope 151 to generate a gyroscope measurement (captured, interpolated, or extrapolated) which is then output as gyroscope data 770. The gyroscope data 770 may include a message 780 which includes timing information (such as a time of or from receipt of the synchronization signal 701 or a timestamp), an external count 702 received as part of synchronization signal 701, and/or an internal count generated by logic 720 of gyroscope 151. In some embodiments a second output (e.g., output 720B) provides a synchronization response signal to image sensor 118 in response to receipt of the synchronization signal. This synchronization response signal may be as basic as an acknowledgement pulse or signal or may be more complex such a stand-alone version of message 780 (depicted) that includes a time of receipt of the synchronization signal 701, a count number generated by the gyroscope logic 730 in response to the synchronization signal 701. In some embodiments (as discussed in more detail in conjunction with FIG. 8B) this synchronization response signal may comprise gyroscope data 770 and/or a message 780.

Responsive to the synchronization signal, gyroscope 151 outputs the time synchronized gyroscope measurement as gyroscope data 770 to EIS system 117 or to an intermediate gyroscope buffer 820. Similarly, image sensor 118 outputs image data 802 that is associated with the synchronization signal 701 either to EIS system 117 or to an intermediate image buffer 810.

EIS system 117 may be implemented on a dedicated processor or its functions may be performed by another processor, such as application processor 110. EIS system 117 will receive both data streams of image data 802 and gyroscope date 770 and will match image data 802 and the gyroscope data 770. EIS system 117 matches up the image data 802 and gyroscope data 770 based on timestamps, content of message 780, time or receipt, a number of a count 702, or other means. EIS system 117 will determine the image transformation(s) required for the image stabilization and will pass the required transformation instructions to the graphical processing unit 119 or to another processor to perform the transformation if it does not perform the transformation(s) itself. GPU 119 may receive image data 802 directly from image buffer 810, or the image data 802 may be passed to GPU 119 from EIS system 117. If no GPU is present in device 100, a dedicated EIS processor or application processor 110 may perform the image processing. GPU 119, completes the electronic stabilization image transformations, as directed, and then outputs a stabilized stream of image data 890. EIS 117 may also receive any other information needed for the image transformation and processing from image sensor 118, such as for example camera data like the intrinsic camera function.

FIG. 8B shows signal flow paths with respect to a block diagram of a portion of an example electronic device 100B, in accordance with various aspects of the present disclosure. FIG. 8B differs from FIG. 8A in that gyroscope data 770 is only provided to from gyroscope 151 to image sensor 118, which then forwards it to EIS, possibly through an intermediate destination such as image buffer 810. The gyroscope data 770 may be incorporated in the image data or may be transmitted separately.

FIG. 9A shows a timing diagram 900A of various signals and data, in accordance with various aspects of the present disclosure. None of the gyroscope data 770 (773A, 775A, and 777A) is supplemented with a message 780. It should be appreciated that each row of gyroscope data 770 describes one of a plurality of ways that a gyroscope 151 can be configured to output gyroscope data 770.

Row A of FIG. 9A illustrates three synchronization signals 701 (701A, 701B, and 701C) that have been output from an image sensor 118 at successive times. The synchronization signals may be received at uniform or non-uniform intervals.

Below this in Row B of FIG. 9A an example of native gyroscope data 773 (773A1, 773A2, 773A3, 773A4, 773A5, 773A6, 773A7) with gyroscope measurements generated and output, conventionally, at the native output data rate (ODR) of gyroscope 151 is depicted. Receipt of a sync signal 701 has no impact on this native ODR, and gyroscope measurements are generated and successively output as gyroscope data at this native ODR.

Below this in Row C of FIG. 9A is an example of gyroscope data 775A (775A1, 775A2, 775A3) generated and output in response to gyroscope 151 receiving synchronization signals 701. In some embodiments, the generated data is captured, while in others it may be extrapolated or interpolated from gyroscope data that is measured at the native ODR. For example, gyroscope data 775A1 is generated and output responsive to receipt of synchronization signal 701A, gyroscope data 775A2 is generated and output responsive to receipt of synchronization signal 701B, gyroscope data 775A3 is generated and output responsive to receipt of synchronization signal 701C.

Below this in Row D of FIG. 9A is an example of a mixture of gyroscope data 770 (773 and 775) that is output from gyroscope 151. Gyroscope data 773A is output at the native ODR of gyroscope 151, while gyroscope data 775A is generated and output in response to gyroscope 151 receiving sync signals 701.

Below this in Row E of FIG. 9A is an example of a mixture of gyroscope data 770 (775, 777) that is output from gyroscope 151. Gyroscope data 775A is generated and output in response to gyroscope 151 receiving sync signals 701. Following the output of gyroscope data 775A1, gyroscope data 777A1, 777A2, 777A3, 777A4, and 777A5 is generated (captured, extrapolated, or interpolated) and output at a set rate of defined time intervals, T1. Following the output of gyroscope data 775A2, gyroscope data 777A6, 777A7, and 777A8 is generated (captured, extrapolated, or interpolated) and output at a set rate of defined time intervals, T1. Following the output of gyroscope data 775A3, gyroscope data 777A9 is generated (captured, extrapolated, or interpolated) and output at interval, T1. T1 may be any suitable amount of time, such as 1 ms, 3 ms, 7 ms, etc. At the expiration of each time period T1 a gyroscope measurement is generated (captured, extrapolated, or interpolated) and then the generated measurement is output. T1 may also be set identical to the native ODR.

FIG. 9B shows a timing diagram 900B of various signals, counts, data, and messages, in accordance with various aspects of the present disclosure. Some of the gyroscope data 770 (773B, 775B, and 777B) is supplemented with a message, designated by a boxed “m,” and some (773A) is not. It should also be appreciated that each row of gyroscope data 770 describes one of a plurality of ways that a gyroscope 151 can be configured to output gyroscope data 770. The output of gyroscope 151 can include gyroscope data 770 with or without a supplemented message 780, and that a message 780 can be output from gyroscope 151 separately from gyroscope data 770. Any message 780 may include, without limitation, one or some combination of: a count received from an external source such as image sensor 118, an internal count generated by gyroscope 151, or timing data (e.g., elapsed time since receipt of the most recent synchronization signal 701, elapsed time since last gyroscope data output; current time timestamp, timestamp of time of receipt of synchronization signal 701, etc.).

Row A of FIG. 9B illustrates three synchronization signals 701 (701A, 701B, and 701C) that have been output from an image sensor 118 at successive times. The synchronization signals may be received at uniform or non-uniform intervals and may include a count number of a count 702 that is generated and output from image sensor 118.

Below this in Row B of FIG. 9B, an example of native gyroscope data 773 (773A1, 773B2, 773B3, 773B4, 773B5, 773B6, 773B7) of gyroscope measurements generated and output, conventionally, at the native output data rate (ODR) of gyroscope 151 is depicted. Receipt of a sync signal 701 has no impact on this native ODR, and gyroscope measurements are generated and successively output as gyroscope data at this native ODR. A message 780, illustrated by a boxed “m,” is supplemented with those of these native ODR outputs that occur after the receipt of a synchronization signal. For example: gyroscope data 773B2 is supplemented with message 780-1; gyroscope data 773B3 is supplemented with message 780-2; gyroscope data 773B4 is supplemented with message 780-3; gyroscope data 773B5 is supplemented with message 780-4; gyroscope data 773B6 is supplemented with message 780-5; gyroscope data 773B7 is supplemented with message 780-6. For example, the messages may be a count and/or a time elapse since the last sync signal, where the count may be an internal or external count.

Below this in Row C of FIG. 9B is an example of gyroscope data 775B (775B1, 775A2, 775A3) generated and output in response to gyroscope 151 receiving synchronization signals 701. In some embodiments, the generated data is captured (actually measured), while in others it may be extrapolated or interpolated from gyroscope data that is measured at the native ODR. For example, gyroscope data 775B1 is generated and output responsive to receipt of synchronization signal 701A and is supplemented with a message 780-7, gyroscope data 775A2 is generated and output responsive to receipt of synchronization signal 701B and is supplemented with a message 780-8, and gyroscope data 775A3 is generated and output responsive to receipt of synchronization signal 701C and is supplemented with a message 780-9. For example, the messages may be an internal or external count.

Below this in Row D of FIG. 9B is an example of a mixture of gyroscope data 770 (773 and 775) that is output from gyroscope 151. Gyroscope data 773 is output at the native ODR of gyroscope 151, while gyroscope data 775 is generated and output in response to gyroscope 151 receiving sync signals 701. As is illustrated some of the gyroscope data (775B1, 775B2, 775B3) is supplemented with a message 780, while some (773A1, 773A2, 773A3, 777A4, 777A5, 777A6, 777A7) is not supplemented with a gyroscope message 780. Although not illustrated, the outputs 773 in Row D of FIG. 9B may be supplemented with data messages 780 in the manner illustrated in Row B of FIG. 9B.

Below this in Row E of FIG. 9B is an example of a mixture of gyroscope data 770 (775, 777) that is output from gyroscope 151. Gyroscope data 775B is generated and output in response to gyroscope 151 receiving sync signals 701. Following the output of gyroscope data 775B1, gyroscope data 777B1, 777B2, 777B3, 777B4, and 777B5 is generated (captured, extrapolated, or interpolated) and output at a set rate of defined time intervals, T1. Gyroscope data 777B1 is supplemented with message 780-10, gyroscope data 777B2 is supplemented with message 780-11, gyroscope data 777B3 is supplemented with message 780-12, gyroscope data 777B4 is supplemented with message 780-13, and gyroscope data 777B5 is supplemented with message 780-14. Following the output of gyroscope data 775A2, gyroscope data 777A6, 777A7, and 777A8 is generated (captured, extrapolated, or interpolated) and output at a set rate of defined time intervals, T1. Gyroscope data 777B6 is supplemented with message 780-15, gyroscope data 777B7 is supplemented with message 780-16, and gyroscope data 777B8 is supplemented with message 780-17. Following the output of gyroscope data 775A3, gyroscope data 777A9 is generated (captured, extrapolated, or interpolated) and output at interval, T1. Gyroscope data 777B9 is supplemented with message 780-18. T1 may be any suitable amount of time, such as 1 ms, 3 ms, 7 ms, etc. At the expiration of each time period T1 a gyroscope measurement is generated (captured, extrapolated, or interpolated) and then the generated measurement is output. T1 may also be set identical to the native ODR. The gyroscope data at the time of the sync signals may contain messages with an internal or external count, and timing information of the next data samples (e.g. T1). In this case, the other data samples in between the sync signals may not contain any messages.

### EXAMPLE METHODS OF OPERATION

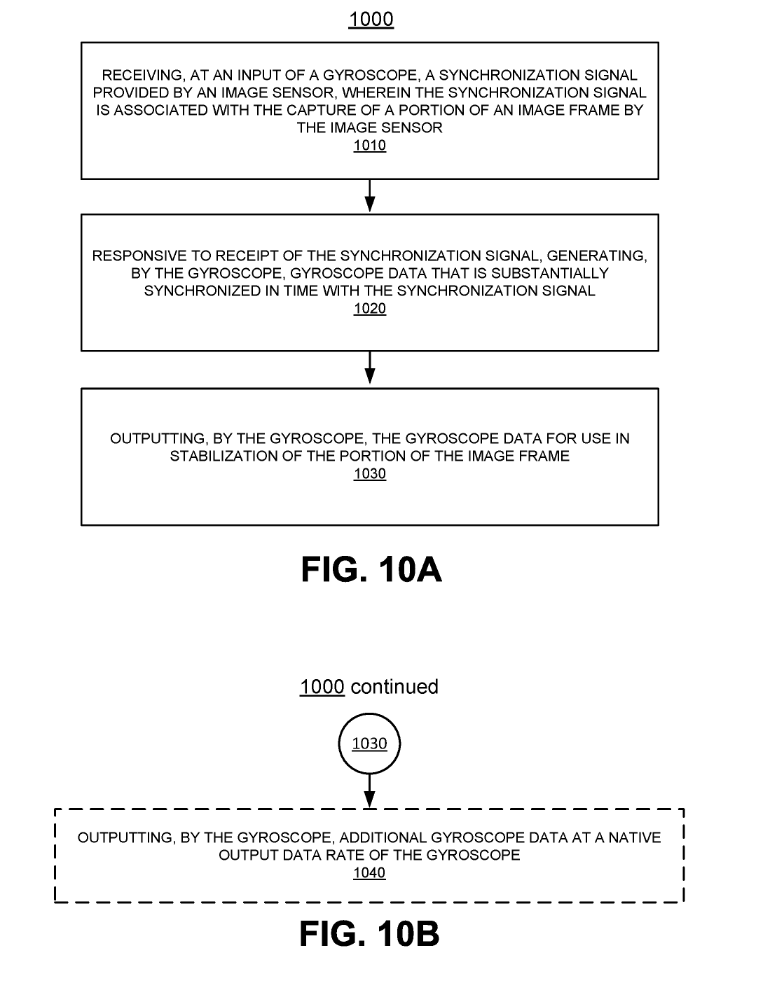

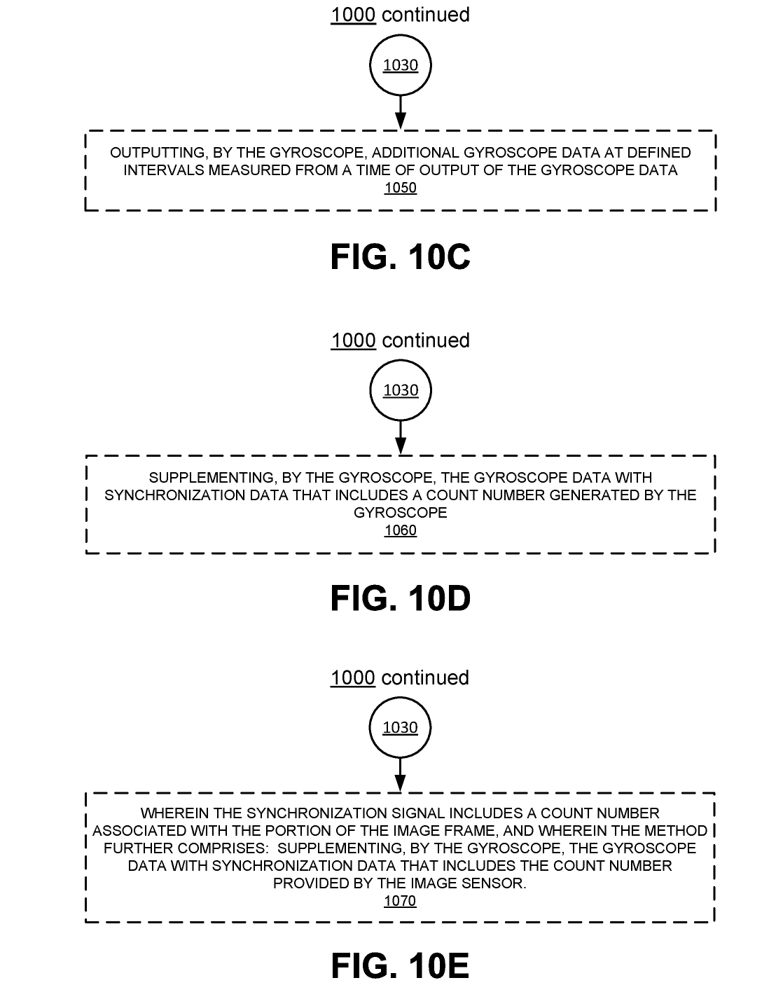

FIGS. 10A-10D illustrate flow diagrams 1000 of an example method of gyroscope operation, in accordance with various aspects of the present disclosure. Procedures of this method will be described with reference to elements and/or components of one or more of FIGS. 1-9B. It is appreciated that in some embodiments, the procedures may be performed in a different order than described, that some of the described procedures may not be performed, and/or that one or more additional procedures to those described may be performed. Flow diagrams 1000 include some procedures that, in various embodiments, are carried out by one or more processors under the control of computer-readable and computer-executable instructions that are stored on non-transitory computer-readable storage media (e.g., application memory 111, internal memory 140, or the like). It is further appreciated that one or more procedures described in flow diagrams 1000 may be implemented in hardware, or a combination of hardware with firmware and/or software.

With reference to FIG. 10A, at procedure 1010 of flow diagram 1000, in various embodiments, at an input of a gyroscope, a synchronization signal is received. The synchronization signal is provided by an image sensor. With reference to FIGS. 1 and 7 this can comprise an input 710 of gyroscope 151 receiving a synchronization signal 701 from image sensor 118. The synchronization signal 701 is associated with the capture of a portion of an image frame captured by the image sensor. The image frame comprises of plurality of lines of image data. The portion of the image frame that the synchronization signal 701 is associated with may be an entire image frame, or less than an entire image frame such as one quarter of an image frame, one line of an image frame, or a sub-portion of a line of an image frame.

With continued reference to FIG. 10A, at procedure 1020 of flow diagram 1000, in various embodiments, responsive to receipt of the synchronization signal the gyroscope generates gyroscope data that is substantially synchronized in time with the synchronization signal. Logic 730 operates to generate and output from gyroscope 151, gyroscope data 770 that is substantially synchronized in time with the receipt of the synchronization signal 701. By “substantially” what is meant is that the output is generated as fast as the gyroscope 151 and any signal propagation delays allow (i.e., as close to the moment as is feasible given delays introduced by signal propagation and processing delays, and yet not far enough from the moment that context is lost). This comprises gyroscope 151 generating gyroscope data 770 (particularly gyroscope data 775 depicted in FIGS. 9A and 9B) in response to synchronization signal 701. In some embodiments, the generating comprises logic 730 directing gyroscope 151 to capture (i.e., to actually directly measure) the gyroscope data 770 in response to the synchronization signal 701. For example, in Row C of FIG. 9A gyroscope data 775A1 may be captured (directly measured) from gyroscope 151 in response to receipt of synchronization signal 701A. In some embodiments, the generating, in response to the synchronization signal 701, comprises interpolating the gyroscope data 770 for the time of receipt of a synchronization signal 701 from native gyroscope data measurements received before and after the synchronization signal 701. For example, in Row C of FIG. 9A gyroscope data 775A1 may be interpolated for the time of receipt of synchronization signal 701A from gyroscope data 773A1 and 773A2 captured before and after synchronization signal 701A. In some embodiments, the generating in response to the synchronization signal, comprises extrapolating the gyroscope data 770 for the time of receipt of a synchronization signal 701 from a most recent previous native gyroscope data measurement, in response to the synchronization signal. For example, in Row C of FIG. 9A gyroscope data 775A1 may be extrapolated for the time of receipt of synchronization signal 701A from gyroscope data 773A1 captured before and after synchronization signal 701A.

With continued reference to FIG. 10A, at procedure 1030 of flow diagram 1000, in various embodiments, outputting, by the gyroscope, the gyroscope data for use in stabilization of the portion of the image frame. For example, with reference to FIG. 7, the gyroscope data 770 is output from one or more outputs 720 (720A, 720B, etc.) of gyroscope 770. The gyroscope data 770 is output for use in image stabilization, such as in optical image stabilization or electronic image stabilization. FIGS. 8A and 8B illustrate examples of gyroscope data 770 being output for use in electronic image stabilization. The gyroscope data 770 may be temporarily stored in a buffer (e.g. gyroscope buffer 820) or may be directly communicated to EIS 117.

With reference to FIG. 10B, at procedure 1040 of flow diagram 1000, in various embodiments, the method as described in 1010-1030 further comprises, outputting, by the gyroscope, additional gyroscope data at a native output data rate of the gyroscope. This can comprise gyroscope 151 additionally generating and outputting gyroscope data 770 (e.g., gyroscope data 773A of FIG. 9A or FIG. 9B) at the native output data rate of gyroscope 151. A first example of this is illustrated in Row D of FIG. 9A and a second example is illustrated in Row D of FIG. 9B.

With reference to FIG. 10C, at procedure 1050 of flow diagram 1000, in various embodiments, the method as described in 1010-1030 further comprises, outputting, by the gyroscope, additional gyroscope data at defined intervals measured from a time of output of the gyroscope data. This can comprise gyroscope 151 additionally generating and outputting gyroscope data 770 (e.g., gyroscope data 777 of FIG. 9A or FIG. 9B) at defined time intervals measured from the time that gyroscope data 775 was output in response to a synchronization signal 701. A first example of this is illustrated in Row E of FIG. 9A and a second example is illustrated in Row E of FIG. 9B.

With reference to FIG. 10D, at procedure 1060 of flow diagram 1000, in various embodiments, the method as described in 1010-1030 further comprises, supplementing, by the gyroscope, the gyroscope data with synchronization data that includes a count number generated by the gyroscope. In some embodiments, logic 730 of gyroscope 151 generates a count with a count number that is incremented, for example, each time that a synchronization signal 701 is received or each time that gyroscope data 770 is generated and output. This can be included in a message 780 that supplements the output of gyroscope data 770. “Supplements” means that the message 780 is included as part of the data package that also includes gyroscope data 770, or is output immediately before or after the output of the gyroscope data 770 with which it is associated.

With reference to FIG. 10E, at procedure 1070 of flow diagram 1000, in various embodiments, the method as described in 1010-1030 further comprises, wherein the synchronization signal includes a count number associated with the portion of the image frame, and wherein the method further comprises: supplementing, by the gyroscope, the gyroscope data with synchronization data that includes the count number provided by the image sensor. In some embodiments, logic 730 of gyroscope 151 receives a count 702 comprises a count number that is generated by image sensor 118, and incremented each time that synchronization signal 701 is sent. The count number of count 702 may be the synchronization signal 701, may be a part of the synchronization signal 701 or may be sent separately from the image signal 701. The count number of count 702 can be included in a message 780 that supplements the output of gyroscope data 770. “Supplements” means that the message 780 is included as part of the data package that also includes the associated gyroscope data, or is output immediately before or after the output of the gyroscope data with which it is associated.

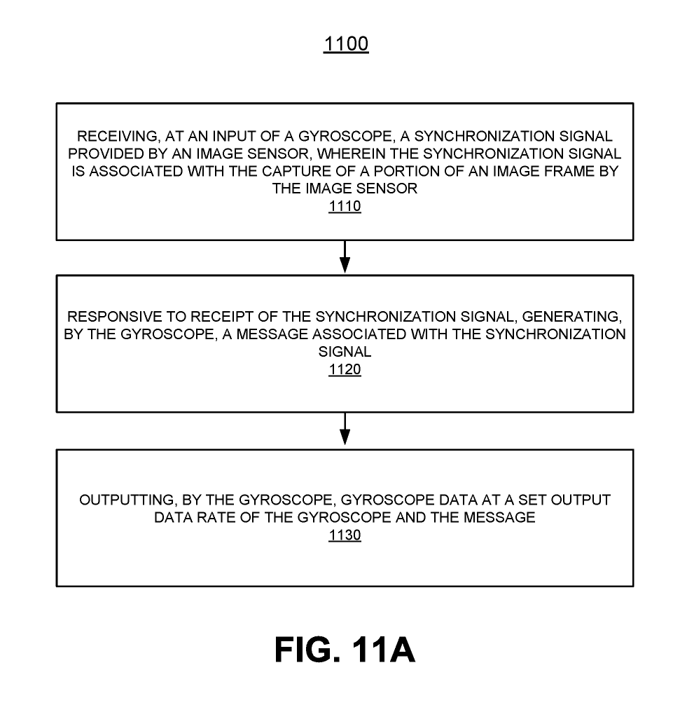

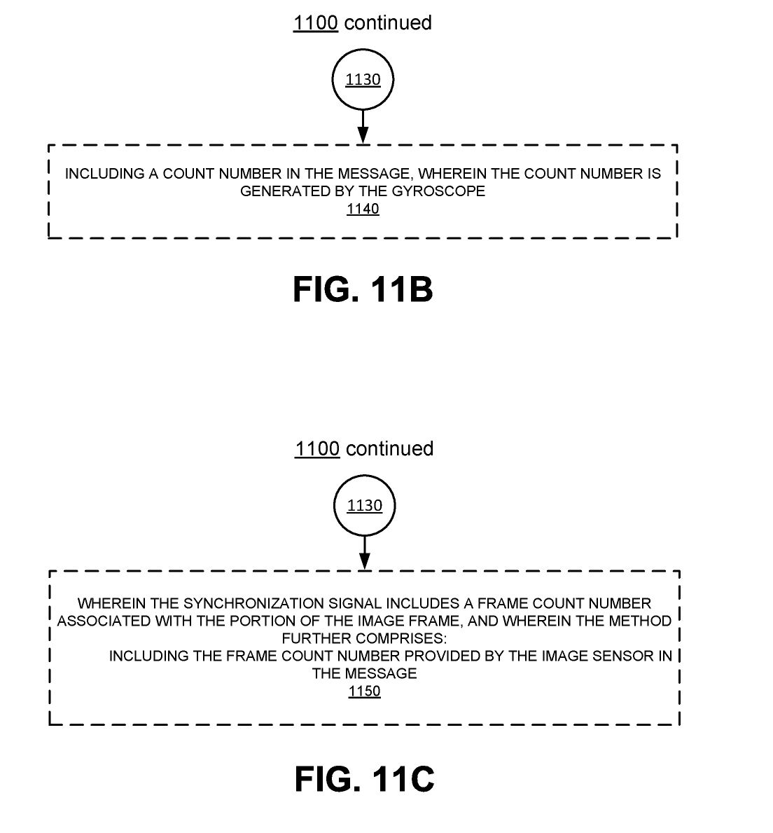

FIGS. 11A-11C illustrate flow diagrams 1100 of an example method of gyroscope operation, in accordance with various aspects of the present disclosure. Procedures of this method will be described with reference to elements and/or components of one or more of FIGS. 1-9B. It is appreciated that in some embodiments, the procedures may be performed in a different order than described, that some of the described procedures may not be performed, and/or that one or more additional procedures to those described may be performed. Flow diagrams 1100 include some procedures that, in various embodiments, are carried out by one or more processors under the control of computer-readable and computer-executable instructions that are stored on non-transitory computer-readable storage media (e.g., application memory 111, internal memory 140, or the like). It is further appreciated that one or more procedures described in flow diagrams 1100 may be implemented in hardware, or a combination of hardware with firmware and/or software.

With reference to FIG. 11A, at procedure 1110 of flow diagram 1100, in various embodiments, at an input of a gyroscope, a synchronization signal is received. The synchronization signal is provided by an image sensor. With reference to FIGS. 1 and 7 this can comprise an input 710 of gyroscope 151 receiving a synchronization signal 701 from image sensor 118. The synchronization signal 701 is associated with the capture of a portion of an image frame captured by the image sensor. The image frame comprises of plurality of lines of image data. The portion of the image frame that the synchronization signal 701 is associated with may be an entire image frame, or less than an entire image frame such as one quarter of an image frame, one line of an image frame or a sub-portion of a line of an image frame.

With continued reference to FIG. 11A, at procedure 1120 of flow diagram 1100, in various embodiments, responsive to receipt of the synchronization signal, the gyroscope generates a message associated with the synchronization signal. This can comprise logic 730 of gyroscope 151 generating a message 780 that is associated with receipt of a synchronization signal 701. Any message 780 may include, without limitation, one or some combination of: a count number of a count received from an external source such as image sensor 118, an internal number of an internal count generated by gyroscope 151, or timing data (e.g., elapsed time since receipt of the most recent synchronization signal 701, elapsed time since last gyroscope data output; current time timestamp, timestamp of a time of receipt of synchronization signal 701, etc.).

With continued reference to FIG. 11A, at procedure 1130 of flow diagram 1100, in various embodiments, outputting, by the gyroscope, gyroscope data at a set output data rate of the gyroscope and the message. This can comprise logic 730 of gyroscope 151 generated gyroscope data 770 at its native output data rate (which may be adjustable) and then outputting the gyroscope data and a message 780. With reference to Row B of FIG. 9B, after receipt of synchronization signal 701A gyroscope data 773B2, 773B3, 777B4 is generated and output at a native output data rate (e.g., 50 Hz, 150 Hz, 1000 Hz, etc.) and is output supplemented with a message 780 (780-1, 780-2, and 780-3, respectively), designated by a boxed “m.” “Supplements” or “supplemented with” means that the message 780 is included as part of the data package that also includes the associated gyroscope data, or is output separately from but immediately before or after the output of the gyroscope data with which it is associated. In some embodiments, the message 780 includes a count number from a count 702 that is provided to the gyroscope 151 by image sensor 118. In some embodiments, the message 780 includes timing information indicative of a time of receipt of the synchronization signal 701 at gyroscope 151. Without limitation, this timing information may comprise a current time timestamp, a timestamp of a time of receipt of synchronization signal 701, an elapsed time since the receipt of the synchronization signal 701, or the like. It should be appreciated that a message 780 may include counts from more than one source and may additionally include timing information along with the count(s).

With reference to FIG. 11B, at procedure 1140 of flow diagram 1100, in various embodiments, the method as described in 1110-1130 further comprises, including a count number in the message, wherein the count number is generated by the gyroscope. In some embodiments, the message 780 includes a count number from a count generated by logic 730 of gyroscope 151.

With reference to FIG. 11C, at procedure 1150 of flow diagram 1100, in various embodiments, the method as described in 1110-1130 further comprises, wherein the synchronization signal includes a count number associated with the portion of the image frame, and wherein the method further comprises: after receipt of the synchronization signal, supplementing a next output of the gyroscope data at the set output data rate with the message. For example, after receipt of the synchronization signal 701, in some embodiments, gyroscope 151 supplements a next output of the gyroscope data at the set output data rate with the message 780. With reference to Row B of FIG. 9B, after receipt of synchronization signal 701A gyroscope data 773B2 is generated and output at a native output data rate (e.g., 50 Hz, 150 Hz, 1000 Hz, etc.) and is output supplemented with a message 780-1, designated by a boxed “m.”

### CONCLUSION

The examples set forth herein were presented in order to best explain, to describe particular applications, and to thereby enable those skilled in the art to make and use embodiments of the described examples. However, those skilled in the art will recognize that the foregoing description and examples have been presented for the purposes of illustration and example only. The description as set forth is not intended to be exhaustive or to limit the embodiments to the precise form disclosed. Rather, the specific features and acts described above are disclosed as example forms of implementing the claims.

Reference throughout this document to “one embodiment,” “certain embodiments,” “an embodiment,” “various embodiments,” “some embodiments,” or similar term means that a particular feature, structure, or characteristic described in connection with the embodiment is included in at least one embodiment. Thus, the appearances of such phrases in various places throughout this specification are not necessarily all referring to the same embodiment. Furthermore, the particular features, structures, or characteristics of any embodiment may be combined in any suitable manner with one or more other features, structures, or characteristics of one or more other embodiments without limitation.

What is claimed is:

1. A method of gyroscope operation, said method comprising:
receiving, at an input of a gyroscope, a synchronization signal provided by an image sensor, wherein said synchronization signal is associated with the capture of a portion of an image frame by said image sensor;
responsive to receipt of said synchronization signal, generating, by said gyroscope, gyroscope data that is substantially synchronized in time with said synchronization signal; and
outputting, by said gyroscope, said gyroscope data for use in stabilization of said portion of said image frame.

2. The method as recited in claim 1, further comprising:
outputting, by said gyroscope, additional gyroscope data at a native output data rate of said gyroscope.

3. The method as recited in claim 1, further comprising:
outputting, by said gyroscope, additional gyroscope data at defined intervals measured from a time of output of said gyroscope data.

4. The method as recited in claim 1, further comprising:
supplementing, by said gyroscope, said gyroscope data with synchronization data that includes a count number generated by said gyroscope.

5. The method as recited in claim 1, wherein said synchronization signal includes a count number associated with said portion of said image frame, and wherein said method further comprises:
supplementing, by said gyroscope, said gyroscope data with synchronization data that includes said count number provided by said image sensor.

6. The method as recited in claim 1, wherein said generating, by said gyroscope, gyroscope data that is substantially synchronized in time with said synchronization signal comprises:
capturing said gyroscope data in response to said synchronization signal.

7. The method as recited in claim 1, wherein said generating, by said gyroscope, gyroscope data that is substantially synchronized in time with said synchronization signal comprises:
in response to said synchronization signal, interpolating said gyroscope data from native gyroscope data measurements received before and after said synchronization signal.

8. The method as recited in claim 1, wherein said generating, by said gyroscope, gyroscope data that is substantially synchronized in time with said synchronization signal comprises:
in response to said synchronization signal, extrapolating said gyroscope data from a most recent previous native gyroscope data measurement.

9. A method of gyroscope operation, said method comprising:
receiving, at an input of a gyroscope, a synchronization signal provided by an image sensor, wherein said synchronization signal is associated with the capture of a portion of an image frame by said image sensor;
responsive to receipt of said synchronization signal, generating, by said gyroscope, a message associated with said synchronization signal; and
outputting, by said gyroscope, gyroscope data at a set output data rate of said gyroscope and said message.

10. The method as recited in claim 9, further comprising:
including a count number in said message, wherein said count number is generated by said gyroscope.

11. The method as recited in claim 9, wherein said synchronization signal includes a count number associated with said portion of said image frame, and wherein said method further comprises:
including said count number in said message, wherein said count number is provided by said image sensor.

12. The method as recited in claim 9, wherein said outputting, by said gyroscope, said gyroscope data at a set output data rate of said gyroscope and said message comprises:
after receipt of said synchronization signal, supplementing a next output of said gyroscope data at said set output data rate with said message.

13. The method as recited in claim 12, wherein said supplementing a next output of said gyroscope data at said set output data rate with said message comprises:
including, in said message, timing information indicative of a time of receipt of said synchronization signal.

14. The method as recited in claim 9, wherein said outputting, by said gyroscope, said gyroscope data at a set output data rate of said gyroscope and said message comprises:
outputting said message independent of said output of said gyroscope data.

15. A gyroscope comprising:
an input configured for receiving a synchronization signal provided by an image sensor, wherein said synchronization signal is associated with the capture of a portion of an image frame by said image sensor; and
logic for generating a message in response to receipt of said synchronization signal; and
at least one output configured for outputting gyroscope data and said message.

16. The gyroscope of claim 15, further comprising:
a second output configured for outputting one of said gyroscope data and said message.

17. The gyroscope of claim 15, wherein said logic is further configured to output said message as a supplement to a next output of said gyroscope data, at a set output data rate, after receipt of said synchronization signal, wherein said message includes at least one of: timing information indicative of a time of receipt of said synchronization signal; a count number generated by said gyroscope; and a count number received from said image sensor and associated with said portion of said image frame.

18. The gyroscope of claim 15, wherein said logic is further configured to output said message independent of said output of said gyroscope data, wherein said message includes at least one of: timing information indicative of a time of receipt of said synchronization signal; a count number generated by said gyroscope; and a count number received from said image sensor and associated with said portion of said image frame.

19. The gyroscope of claim 15, wherein said logic is further configured to:
capture said gyroscope data in response to said synchronization signal; and
output said captured gyroscope data supplemented with said message, wherein said message includes at least one of: a count number generated by said gyroscope; and a count number received from said image sensor and associated with said portion of said image frame.

20. The gyroscope of claim 15, wherein said logic is further configured to:
interpolate gyroscope data from a most recent native gyroscope data measurement previous to receipt of said synchronization signal; and
output said interpolated gyroscope data supplemented with said message, wherein said message includes at least one of: a count number generated by said gyroscope; and a count number received from said image sensor and associated with said portion of said image frame.

21. An image stabilization system comprising:
an image sensor configured to output a synchronization signal associated with the capture of a portion of an image frame; and
a gyroscope comprising:
an input configured for receiving said synchronization signal from said image sensor;
logic for generating a message in response to receipt of said synchronization signal; and
an output configured for outputting gyroscope data; and
a processor configured for utilizing said gyroscope data to stabilize said portion of said image frame.

22. The image stabilization system of claim 21, wherein said gyroscope further comprises:
a second output configured for outputting a synchronization response signal to said image sensor in response to receipt of said synchronization signal.

23. The image stabilization system of claim 22, wherein the synchronization response signal includes at least one of: gyroscope data; timing information indicative of a time of receipt of said synchronization signal; and a count number generated by said gyroscope.

24. The image stabilization system of claim 21, wherein said output of said gyroscope data occurs at a native output data rate of said gyroscope, and wherein said output is further configured to output a message that includes at least one of: timing information indicative of a time of receipt of said synchronization signal; a count number generated by said gyroscope; and a count number received from said image sensor and associated with said portion of said image frame.

25. The image stabilization system of claim 24, wherein said processor is further configured for utilizing both said gyroscope data and said message to stabilize said portion of said image frame.

26. The image stabilization system of claim 24, wherein output of said gyroscope data is substantially synchronized with receipt of said synchronization signal.

27. The image stabilization system of claim 21, wherein output of said gyroscope is transmitted to the image sensor.
